(19) United States
(12) Patent Application Publication
(10) Pub. No.: US 2024/0379795 A1
(43) Pub. Date: Nov. 14, 2024

(54) SEMICONDUCTOR DEVICES

(71) Applicant: SAMSUNG ELECTRONICS CO., LTD., Suwon-si (KR)

(72) Inventors: Wooseok PARK, Suwon-si (KR); Taehyun RYU, Suwon-si (KR); Namhyun LEE, Suwon-si (KR)

(21) Appl. No.: 18/504,981

(22) Filed: Nov. 8, 2023

(30) Foreign Application Priority Data
May 11, 2023 (KR) 10-2023-0061275

(51) Int. Cl. H01L 29/423; H01L 29/06; H01L 29/775; H01L 29/786

(52) U.S. Cl. CPC H01L 29/42392; H01L 29/0673; H01L 29/775; H01L 29/78696

(57) ABSTRACT

A semiconductor device comprising: a substrate; a first lower pattern on the substrate; a second lower pattern on the first lower pattern; channel patterns on the second lower pattern; a first field insulating layer on a first side surface of the first lower pattern; a second field insulating layer on a second side surface of the first lower pattern; a buried insulating structure on the first field insulating layer and on side surfaces of the channel patterns; a protective layer on the second field insulating layer; source/drain patterns on sides of each of the channel patterns; and a gate electrode extending around the channel patterns and the buried insulating structure, wherein the protective layer comprises: a protective insulating layer between the first lower pattern and the second lower pattern, and between the gate electrode and the second field insulating layer; and a protective liner extending around the protective insulating layer.

### CROSS-REFERENCE TO RELATED APPLICATION

This application claims priority to and the benefit of Korean Patent Application No. 10-2023-0061275 filed in the Korean Intellectual Property Office on May 11, 2023, the entire contents of which are incorporated herein by reference.

### BACKGROUND

The present disclosure relates to semiconductor devices.

Semiconductors are materials falling within the intermediate category between conductors and nonconductors, and refer to materials conducting electricity under predetermined conditions. Such semiconductor materials may be used to manufacture various semiconductor devices, for example, to manufacture memory devices and so on. These semiconductor devices may be used in various electronic devices.

As the electronics industry has highly been developing, the demands for the characteristics of semiconductor devices have been gradually increasing. For example, the demands for semiconductor devices with higher reliability, higher speed, and/or more functions have been gradually increasing. In order to obtain these required characteristics, the structures in semiconductor devices have gradually become complicated and have been integrated at higher densities. As the sizes of transistors decrease, coupling between elements may occur, whereby the degrees of reliability of semiconductor devices may decrease while the operating speeds of the semiconductor devices may decrease.

### SUMMARY

The present disclosure may provide semiconductor devices with improved reliability.

An embodiment of the present disclosure may provide a semiconductor device comprising: a substrate; a first lower pattern on the substrate; a second lower pattern on the first lower pattern; channel patterns on the second lower pattern; a first field insulating layer on a first side surface of the first lower pattern; a second field insulating layer on a second side surface of the first lower pattern; a buried insulating structure on the first field insulating layer and on side surfaces of the channel patterns; a protective layer on the second field insulating layer; source/drain patterns on opposite sides of each of the channel patterns; and a gate electrode extending around at least some portions of the channel patterns and the buried insulating structure, wherein the protective layer comprises: a protective insulating layer between the first lower pattern and the second lower pattern, and between the gate electrode and the second field insulating layer; and a protective liner extending around the protective insulating layer.

Another embodiment of the present disclosure may provide a semiconductor device comprising: a substrate; a first lower pattern extending in a first direction on the substrate; a second lower pattern on the first lower pattern; channel patterns on the second lower pattern; a first field insulating layer on a first side surface of the first lower pattern; a second field insulating layer on a second side surface of the first lower pattern; a buried insulating structure extending in the first direction on the first field insulating layer and on side surfaces of the channel patterns; source/drain patterns on opposite sides of each of the channel patterns; a gate electrode extending in a second direction intersecting with the first direction and extending around at least some portions of the channel patterns and the buried insulating structure; and a protective layer between the first lower pattern and the second lower pattern, and between the second field insulating layer and the gate electrode, wherein a first thickness of the protective layer between the first lower pattern and the second lower pattern is smaller than or equal to a second thickness of the protective layer between the second field insulating layer and the gate electrode.

Yet another embodiment of the present disclosure may provide a semiconductor device comprising: a substrate; a first lower pattern on the substrate; a second lower pattern on the first lower pattern; channel patterns on the second lower pattern; a first field insulating layer on a first side surface of the first lower pattern; a second field insulating layer on a second side surface of the first lower pattern; a buried insulating structure on the first field insulating layer and on side surfaces of the channel patterns; a protective layer on the second field insulating layer; source/drain patterns on opposite sides of each of the channel patterns; and a gate electrode extending around at least some portions of the channel patterns and the buried insulating structure, wherein the protective layer comprises: a protective insulating layer between the first lower pattern and the second lower pattern, and between the gate electrode and the second field insulating layer; and a protective liner extending around the protective insulating layer, and wherein a first distance between the second lower pattern and the first lower pattern is smaller than or equal to a second distance between the gate electrode and the second field insulating layer.

According to some embodiments of the present inventive concepts, a semiconductor device may include a protective layer between a second field insulating layer and a gate electrode and between a first lower pattern and a second lower pattern, thereby being capable of reducing leakage current occurring between a gate structure and an adjacent source/drain pattern. Therefore, the present inventive concepts may improve the reliability of the semiconductor device.

### BRIEF DESCRIPTION OF THE DRAWINGS

FIG. 1 is a plan view illustrating a semiconductor device according to some embodiments.

FIG. 2A is a cross-sectional view taken along line A-A′ in FIG. 1.

FIG. 2B is a cross-sectional view taken along line B-B′ in FIG. 1.

FIG. 2C is a cross-sectional view taken along line C-C′ in FIG. 1.

FIG. 2D is a cross-sectional view taken along line D-D′ in FIG. 1.

FIG. 3A is an enlarged cross-sectional view of region S in FIG. 2A.

FIG. 3B is a cross-sectional view illustrating a semiconductor device according to some embodiments and corresponding to line C-C′ in FIG. 1.

FIG. 4 is an enlarged cross-sectional view of region P in FIG. 2C.

FIG. 5 is an enlarged cross-sectional view of region Q in FIG. 2D.

FIG. 6 and FIG. 7 are enlarged cross-sectional views illustrating a semiconductor device according to some embodiments and corresponding to region P in FIG. 2C.

FIG. 8 is an enlarged cross-sectional view illustrating a semiconductor device according to some embodiments and corresponding to region Q in FIG. 2D.

FIG. 9 to FIG. 12 are cross-sectional views illustrating intermediate steps of a method of manufacturing a buried insulating structure of a semiconductor device according to some embodiments and corresponding to line C-C′ in FIG. 1.

FIG. 13, FIG. 15, FIG. 17, FIG. 19, FIG. 21, FIG. 23, FIG. 25, FIG. 27, FIG. 29, and FIG. 31 are plan views illustrating intermediate steps of a method of manufacturing a semiconductor device according to some embodiments.

FIG. 14A is a cross-sectional view taken along line A-A′ in FIG. 13.

FIG. 14B is a cross-sectional view taken along line B-B′ in FIG. 13.

FIG. 14C is a cross-sectional view taken along line C-C′ in FIG. 13.

FIG. 14D is a cross-sectional view taken along line D-D′ in FIG. 13.

FIG. 16A is a cross-sectional view taken along line A-A′ in FIG. 15.

FIG. 16B is a cross-sectional view taken along line B-B′ in FIG. 15.

FIG. 16C is a cross-sectional view taken along line C-C′ in FIG. 15.

FIG. 16D is a cross-sectional view taken along line D-D′ in FIG. 15.

FIG. 18A is a cross-sectional view taken along line A-A′ in FIG. 17.

FIG. 18B is a cross-sectional view taken along line B-B′ in FIG. 17.

FIG. 18C is a cross-sectional view taken along line C-C′ in FIG. 17.

FIG. 18D is a cross-sectional view taken along line D-D′ in FIG. 17.

FIG. 20A is a cross-sectional view taken along line A-A′ in FIG. 19.

FIG. 20B is a cross-sectional view taken along line B-B′ in FIG. 19.

FIG. 20C is a cross-sectional view taken along line C-C′ in FIG. 19.

FIG. 20D is a cross-sectional view taken along line D-D′ in FIG. 19.

FIG. 22A is a cross-sectional view taken along line A-A′ in FIG. 21.

FIG. 22B is a cross-sectional view taken along line B-B′ in FIG. 21.

FIG. 22C is a cross-sectional view taken along line C-C′ in FIG. 21.

FIG. 22D is a cross-sectional view taken along line D-D′ in FIG. 21.

FIG. 24A is a cross-sectional view taken along line A-A′ in FIG. 23.

FIG. 24B is a cross-sectional view taken along line B-B′ in FIG. 23.

FIG. 24C is a cross-sectional view taken along line C-C′ in FIG. 23.

FIG. 24D is a cross-sectional view taken along line D-D′ in FIG. 23.

FIG. 26A is a cross-sectional view taken along line A-A′ in FIG. 25.

FIG. 26B is a cross-sectional view taken along line B-B′ in FIG. 25.

FIG. 26C is a cross-sectional view taken along line C-C′ in FIG. 25.

FIG. 26D is a cross-sectional view taken along line D-D′ in FIG. 25.

FIG. 28A is a cross-sectional view taken along line A-A′ in FIG. 27.

FIG. 28B is a cross-sectional view taken along line B-B′ in FIG. 27.

FIG. 28C is a cross-sectional view taken along line C-C′ in FIG. 27.

FIG. 28D is a cross-sectional view taken along line D-D′ in FIG. 27.

FIG. 30A is a cross-sectional view taken along line A-A′ in FIG. 29.

FIG. 30B is a cross-sectional view taken along line B-B′ in FIG. 29.

FIG. 30C is a cross-sectional view taken along line C-C′ in FIG. 29.

FIG. 30D is a cross-sectional view taken along line D-D′ in FIG. 29.

FIG. 32A is a cross-sectional view taken along line A-A′ in FIG. 31.

FIG. 32B is a cross-sectional view taken along line B-B′ in FIG. 31.

FIG. 32C is a cross-sectional view taken along line C-C′ in FIG. 31.

FIG. 32D is a cross-sectional view taken along line D-D′ in FIG. 31.

### DETAILED DESCRIPTION OF THE EMBODIMENTS

In the following detailed description, only certain embodiments have been shown and described, simply by way of illustration. The present invention can be variously implemented and is not limited to the following embodiments.

The drawings and description are to be regarded as illustrative in nature and not restrictive. Like reference numerals may designate like elements throughout the specification.

In addition, the size and thickness of each configuration shown in the drawings may be arbitrarily shown for understanding and ease of description, but the present invention is not limited thereto. In the drawings, the thickness of layers, films, panels, regions, etc., may be exaggerated for clarity. In the drawings, for understanding and ease of description, the thickness of some layers and areas may be exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

The terminology used herein is for the purpose of describing particular embodiments only and is not intended to limit the present disclosure. As used herein, the singular forms are intended to include the corresponding plural forms as well and the plural forms are intended to include the corresponding singular forms as well, unless the context clearly indicates otherwise. In addition, unless explicitly described to the contrary, the word “comprise”, and variations such as “comprises” or “comprising”, will be understood to imply the inclusion of stated elements but not the exclusion of any other elements.

Further, throughout this specification, when it is referred to as “on a plane”, it means when a target part is viewed from above, and when it is referred to as “on a cross-section”, it means when the cross-section obtained by cutting a target part vertically is viewed from the side.

The drawings related to a semiconductor device according to some embodiments show a transistor including nanowires or nanosheets, a multi-bridge channel field effect transistor (MBCFET™), and a fin-type transistor (FinFET) including a channel region having a fin channel shape as examples, but the present disclosure is not limited thereto. The semiconductor device according to some embodiments may include tunneling FETs, 3D stack field effect transistors (3DSFETs), complementary field effect transistors (CFETs), etc.

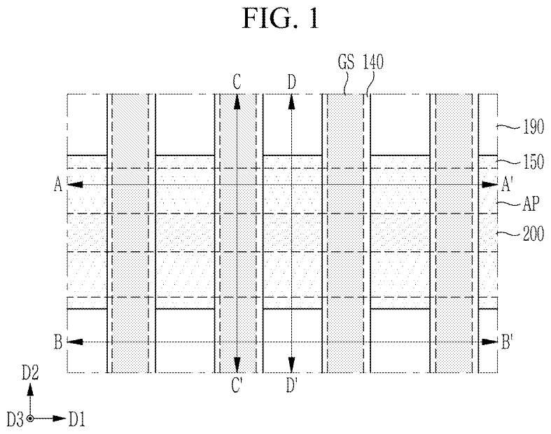

Hereinafter, a semiconductor device according to some embodiments will be described with reference to FIG. 1 to FIG. 3B.

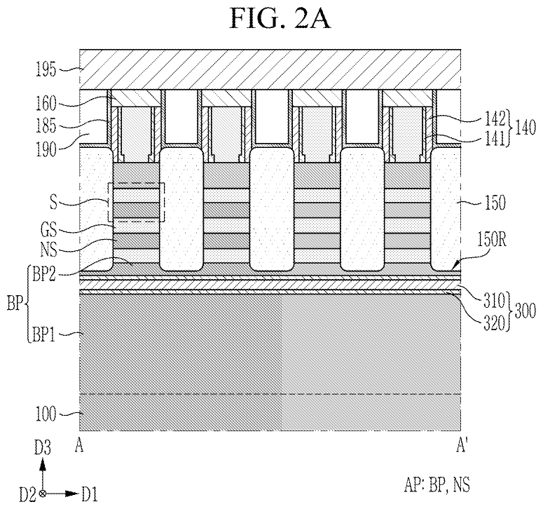

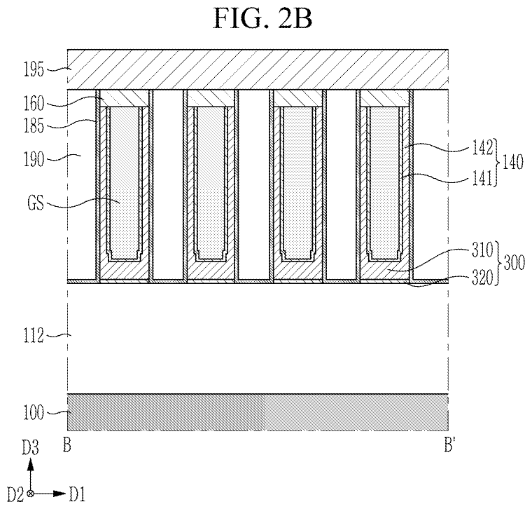

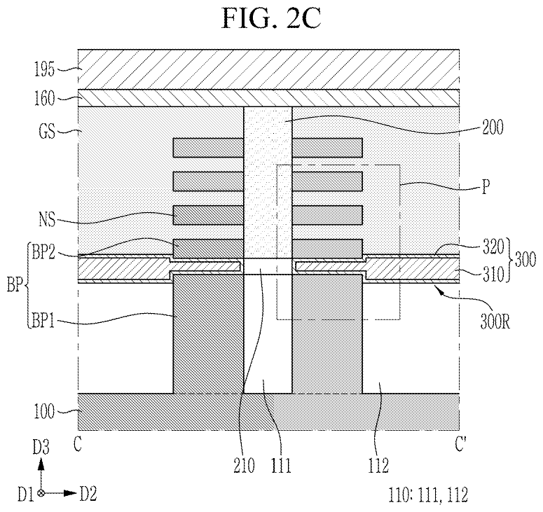

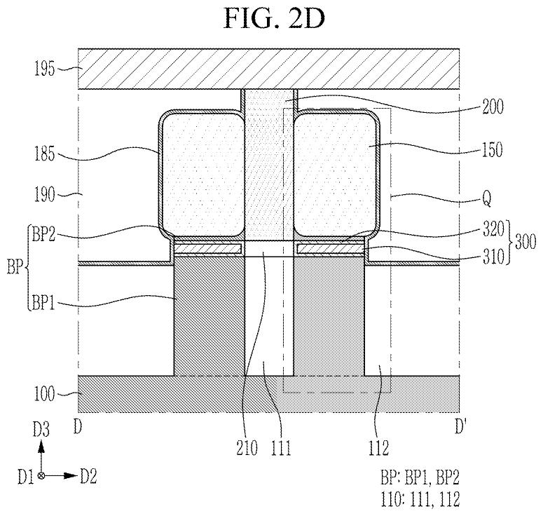

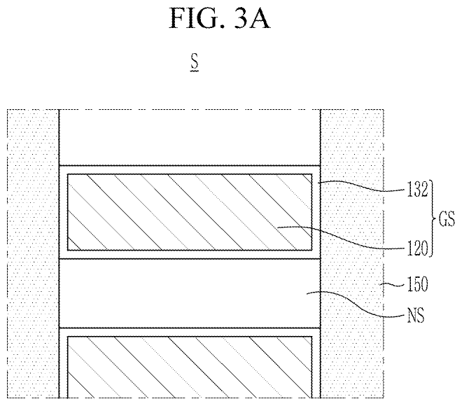

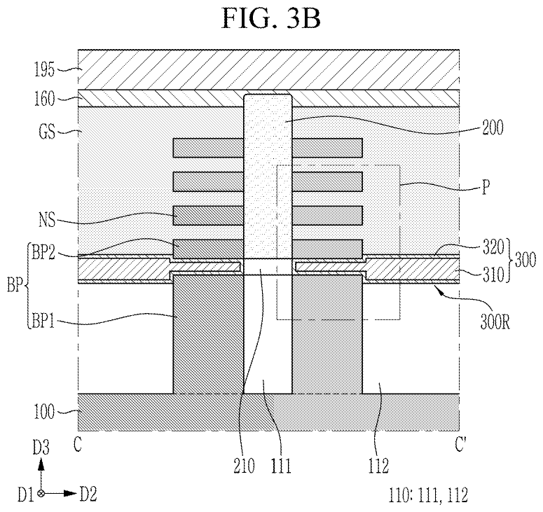

FIG. 1 is a plan view illustrating a semiconductor device according to some embodiments. FIG. 2A is a cross-sectional view taken along line A-A′ in FIG. 1. FIG. 2B is a cross-sectional view taken along line B-B′ in FIG. 1. FIG. 2C is a cross-sectional view taken along line C-C′ in FIG. 1. FIG. 2D is a cross-sectional view taken along line D-D′ in FIG. 1. FIG. 3A is an enlarged cross-sectional view of region S in FIG. 2A. FIG. 3B is a cross-sectional view illustrating a semiconductor device according to some embodiments and corresponding to line C-C′ in FIG. 1.

Referring to FIG. 1 to FIG. 3A, a semiconductor device according to some embodiments may include a substrate 100, active patterns AP located on the substrate 100, field insulating layers 110 located between the active patterns AP, a buried insulating structure 200 located on the field insulating layers 110, gate structures GS extending around (e.g., surrounding) at least a portion of the active patterns AP, source/drain patterns 150 located on sides (e.g., opposite sides) of the gate structures GS, and a protective layer 300 located between the field insulating layers 110 and the gate structures GS.

The substrate 100 may include a bulk silicon or a silicon-on-insulator (SOI). In some embodiments, the substrate 100 may include a silicon substrate, or may contain other materials such as silicon germanium (SiGe), silicon germanium on insulator (SGOI), indium antimonide, a lead tellurium compound, indium arsenide, indium phosphide, gallium arsenide, or gallium antimonide, but is not limited thereto. An upper surface of the substrate 100 may be formed as a plane parallel with a first direction D1 and a second direction D2 intersecting with (e.g., perpendicular to) the first direction D1.

The active patterns AP may be located on the substrate 100. The active patterns AP may protrude from the substrate 100. The active patterns AP may extend long in the first direction D1. The active patterns AP may protrude in a third direction D3 from the upper surface of the substrate 100. The third direction D3 may be perpendicular to the upper surface of the substrate 100. The third direction D3 may intersect with (e.g., perpendicular to) the first direction D1 and the second direction D2. The active patterns AP may be located so as to be apart from one another in the second direction D2. In some embodiments, the active patterns AP may be located in regions where PMOSs are formed. In some embodiments, the active patterns AP may be located in regions where NMOSs are formed. For example, of active patterns AP located on both sides of a buried insulating structure 200 to be described below, one may be located in a region where a PMOS is formed and the other one may be located in a region where an NMOS is formed; however, the locations of the active patterns AP are not limited thereto.

The active patterns AP may be multi-channel active patterns. The active patterns AP may include lower patterns BP and a plurality of channel patterns NS. The lower patterns BP may include first lower patterns BP1 and second lower patterns BP2.

The first lower patterns BP1 may be located on the substrate 100. The second lower patterns BP2 may be located on the first lower patterns BP1. The first lower patterns BP1 and the second lower patterns BP2 may protrude from the substrate 100. The first lower patterns BP1 and the second lower patterns BP2 may extend in the first direction D1. The first lower patterns BP1 and the second lower patterns BP2 may be separated in the third direction D3 by the protective layer 300 to be described below. In other words, the protective layer 300 may be located between the first lower patterns BP1 and the second lower patterns BP2.

The plurality of channel patterns NS may be located on an upper surface of the lower patterns BP. The plurality of channel patterns NS may be separated from the lower patterns BP in the third direction D3. On one lower pattern BP, the plurality of channel patterns NS may be located so as to be separate from one another in the third direction D3.

FIG. 2A and FIG. 2C show that the plurality of channel patterns NS includes three channel patterns NS stacked so as to be apart from one another in the third direction D3; however, this is merely for ease of explanation, and the present invention is not limited thereto. For example, the plurality of channel patterns NS may include two channel patterns NS stacked so as to be apart from each other in the third direction D3, or four or more channel patterns NS may be stacked so as to be apart from one another in the third direction D3.

FIG. 3A shows that side surfaces (e.g., opposite side surfaces) of the channel patterns NS may be planar surfaces; however, the present invention is not limited thereto. For example, the side surfaces of the channel patterns NS may be combinations of curved surfaces and planar surfaces, and may be generally curved surfaces.

The lower patterns BP may be formed by etching portions of the substrate 100, and may include epitaxial layers grown from the substrate 100. The lower patterns BP may contain silicon (Si) and/or germanium (Ge) which is an elemental semiconductor material. Also, the lower patterns BP may contain a compound semiconductor, and may contain, for example, a IV-IV compound semiconductor or a III-V compound semiconductor.

The IV-IV compound semiconductor may be, for example, a binary compound, or a ternary compound containing at least two of carbon (C), silicon (Si), germanium (Ge), and tin (Sn).

The III-V compound semiconductor may be, for example, one of binary compounds, ternary compounds, and quaternary compounds which are formed by bonding of at least one of aluminum (Al), gallium (Ga), and indium (In) which are group III elements and at least one of phosphorus (P), arsenic (As), and antimony (Sb) which are group V elements.

The channel patterns NS may contain one of silicon (Si) and silicon germanium (SiGe) which are elemental semiconductor materials, IV-IV compound semiconductors, and III-V compound semiconductors. The individual channel patterns NS may contain the same material as that in the lower patterns BP, and may contain a material different from that in the lower patterns BP.

In the semiconductor device according to some embodiments, the lower patterns BP may be lower silicon patterns containing silicon (Si), and the channel patterns NS may be silicon sheet patterns containing silicon (Si).

The field insulating layers 110 may be located on the substrate 100. The field insulating layers 110 may be located on side surfaces of the first lower patterns BP1. The field insulating layers 110 may not be located on the upper surface of the first lower patterns BP1. The field insulating layers 110 may extend around (e.g., cover) portions of the side surfaces of the first lower patterns BP1, or the entire side surfaces. Each channel patterns NS among the plurality of channel patterns NS may be located higher than the upper surface of the field insulating layers 110. Hereinafter, “high”, “higher”, “height”, or the like may refer to relative distances from a lower surface of the substrate 100 in the third direction D3. For example, the plurality of channel patterns NS may be farther than the upper surface of the field insulating layers 110 from a lower surface of the substrate 100 in the third direction D3.

The field insulating layers 110 may include first field insulating layer 111 and second field insulating layer 112 located on the sides of the lower patterns BP. The first field insulating layer 111 may be located on one side surfaces (also referred to as first side surfaces) of the first lower patterns BP1, and may overlap the buried insulating structure 200 (to be described below) in the third direction D3. The second field insulating layer 112 may be located on the other side surfaces (also referred to as second side surfaces or the opposite side surfaces) of the first lower patterns BP1, and may not overlap the buried insulating structure 200 in the third direction D3.

The first field insulating layer 111 may cover some entire side surfaces (e.g., the entire first side surfaces) of the first lower patterns BP1. Therefore, the upper surface of the first field insulating layer 111 may be located at substantially the same height level as the upper surface of the first lower patterns BP1. In this case, the first field insulating layer 111 may overlap the buried insulating structure 200 (to be described below) in the third direction D3. Also, the first field insulating layer 111 may overlap insulating pattern 210 (to be described below) in the third direction D3.

The second field insulating layer 112 may cover portions of the other side surfaces (e.g., portions of the second side surfaces or portions of the opposite side surfaces) of the first lower patterns BP1. In some embodiments, an upper surface of the second field insulating layer 112 may be located at a height level lower than that of the upper surface of the first lower patterns BP1. The upper surface of the second field insulating layer 112 may be located at a height level lower than that of the upper surface of the first field insulating layer 111. However, unlike in the drawings, the second field insulating layer 112 may entirely cover the other side surfaces (e.g., also referred to a as the second side surfaces or the opposite side surfaces) of the first lower patterns BP1.

However, the present invention is not limited thereto, and the first field insulating layer 111 and the second field insulating layer 112 may cover portions of side surfaces of the lower patterns BP. In this case, some portions of the lower patterns BP may protrude in the third direction D3 from the upper surface of the field insulating layers 110 (e.g., the first and second field insulating layers 111 and 112).

The field insulating layers 110 may contain a material having etch selectivity to the insulating patterns 210. For example, the field insulating layers 110 may contain silicon oxide (SiO₂) having a denser structure than the insulating patterns 210 have, but are not limited thereto. The first field insulating layer 111 and the second field insulating layer 112 may each contain, for example, silicon nitride (SiN), silicon oxynitride (SiON), or a combination layer thereof. In the drawings, each field insulating layer 110 is shown as a single layer; however, this is merely for ease of explanation, and the field insulating layers are not limited thereto.

The buried insulating structure 200 may be located on the first field insulating layer 111. The buried insulating structure 200 may be located between the side surfaces (e.g., the opposite side surfaces) of the second lower patterns BP2. For example, the buried insulating structure 200 may overlaps the second lower patterns BP2 in the second direction D2.

The buried insulating structure 200 may be located between the side surfaces (e.g., the opposite side surfaces) of the channel patterns NS. The buried insulating structure 200 may overlaps the channel patterns NS in the second direction D2. The buried insulating structure 200 may abut on the side surfaces of the channel patterns NS. Also, the buried insulating structure 200 may abut (e.g., may be) on side surfaces of the gate structures GS located between adjacent channel patterns NS in the third direction D3. In other words, the side surfaces of the buried insulating structure 200 may abut (e.g., may be) on the side surfaces of stacked structures formed by alternately stacking the gate structures GS and the channel patterns NS. The buried insulating structure 200 may extend in the first direction D1.

The buried insulating structure 200 may be located between the first field insulating layer 111 and the gate structures GS. For example, the buried insulating structure 200 may be located between the insulating patterns 210 located on the first field insulating layer 111 to be described below and the gate structures GS. The buried insulating structure 200 may overlap the insulating patterns 210 in the third direction D3. The buried insulating structure 200 may overlap the gate structures GS in the third direction D3.

The upper surface of the buried insulating structure 200 may be located at a height level higher than that of an upper surface of an uppermost channel pattern NS among the channel patterns NS. The upper surface of the buried insulating structure 200 may be located farther from the upper surface of the substrate 100 than the upper surface of the uppermost channel pattern NS is. In other words, the buried insulating structure 200 may protrude in the third direction D3 further than the uppermost channel pattern NS does.

The upper surface of the buried insulating structure 200 may be located at the substantially same height level with that of the upper surface of the gate structures GS. However, the present invention is not limited thereto, and as shown in FIG. 3B, the buried insulating structure 200 may protrude in the third direction D3 from the upper surface of the gate structures GS. In other words, the upper surface of the buried insulating structure 200 may be located at a height level higher than that of the upper surface of the gate structures GS. The upper surface of the buried insulating structure 200 may be located in gate capping layers 160 located on the gate structures GS. In some embodiments, the buried insulating structure 200 may extend in (e.g., pass through) the gate capping layers 160.

The buried insulating structure 200 may contain a low-dielectric constant material. Also, the buried insulating structure 200 may contain a material having etch selectivity to the channel patterns NS. The buried insulating structure 200 may contain, for example, silicon nitride (SiN), silicon carbonitride (SiCN), silicon oxycarbide (SiOC), and/or low-dielectric constant materials, but are not limited thereto.

When the distance between channel patterns NS adjacent to each other in the second direction D2 decreases, coupling may occur between the channel patterns NS adjacent to each other in the second direction D2. Accordingly, the reliability of the semiconductor device may decrease. In the semiconductor device according to some embodiments, the buried insulating structure 200 may contain a low-dielectric constant material, whereby coupling between channel patterns NS adjacent to each other in the second direction D2 may be improved (e.g., reduce). In other words, it is possible to improve the degree of integration of the semiconductor device.

The semiconductor device according to some embodiments may further include the insulating patterns 210.

The insulating patterns 210 may be located on the first field insulating layer 111. The insulating patterns 210 may be located between the buried insulating structure 200 and the first field insulating layer 111. In other words, the insulating patterns 210 may overlap the buried insulating structure 200 in the third direction D3. The insulating patterns 210 may overlap the first field insulating layer 111 in the third direction D3. A lower surface of the insulating patterns 210 may abut (e.g., may be) on the first field insulating layer 111. An upper surface of the insulating patterns 210 may abut (e.g., may be) on the buried insulating structure 200. The insulating patterns 210 may extend in the first direction D1.

The insulating patterns 210 may be located between side surfaces of the protective layer 300 to be described below. Specifically, the insulating patterns 210 may overlap the protective layer 300 in the second direction D2, and be located between the side surfaces of the protective layer 300. The side surfaces of the insulating patterns 210 may abut (e.g., may be) on the protective layer 300. For example, the upper surface of the insulating patterns 210 may abut (e.g., may be) on the buried insulating structure 200. The lower surface of the insulating patterns 210 may abut (e.g., may be) on the first field insulating layer 111. The side surfaces of the insulating patterns 210 may abut (e.g., may be) on first vertical parts 320_V1 of protective liner 320 to be described below.

The insulating patterns 210 may contain a material having etch selectivity to the field insulating layers 110. For example, the insulating patterns 210 may contain silicon oxide (SiO₂) that is less dense than the field insulating layers 110, but are not limited thereto. As an example, the insulating patterns 210 may contain silicon nitride (SiN), silicon oxynitride (SiON), or a combination layer thereof. Although each of insulating patterns 210 is shown as a single layer in the drawings, this is merely for ease of explanation, and the insulating patterns 210 are not limited thereto.

In this case, the degrees of densification of the materials which are contained in the field insulating layers 110 and the insulating patterns 210 may be determined depending on the annealing temperatures of silicon oxide (SiO₂), the numbers of times of annealing, etc., in the processes of forming the field insulating layers 110 and the insulating patterns 210. For example, as the number of times of annealing increases, silicon oxide (SiO₂) may become denser.

In FIG. 2C, the insulating patterns 210 are shown so as to be distinguished from the first field insulating layer 111; however, in some embodiments, the insulating patterns 210 may not be distinguished from the first field insulating layer 111. For example, the insulating patterns 210 and the first field insulating layer 111 may contain the same material, such that no boundary is formed (e.g., distinguishably shown) between the insulating patterns 210 and the first field insulating layer 111.

The gate structures GS may be located on the substrate 100. The gate structures GS may extend in the second direction D2. The gate structures GS may be located apart from one another in the first direction D1.

The gate structures GS may be located on the active patterns AP. The gate structures GS may intersect with (e.g., cross) the active patterns AP in a plane. The gate structures GS may intersect with (e.g., cross) the lower patterns BP in a plane.

The gate structures GS may extend around (e.g., surround) at least some portions of the individual channel patterns NS among the plurality of channel patterns NS. The gate structures GS may surround at least some portions of the buried insulating structure 200. For example, the gate structures GS may extend around (e.g., surround) at least some portions of the channel patterns NS by covering one side surfaces (also referred to as first side surfaces) of the channel patterns NS and lower surfaces and upper surfaces of the channel patterns NS. For example, the gate structures GS may cover a first side surface, a lower surface, and an upper surface of each of the channel patterns NS. Also, the gate structures GS may extend around (e.g., surround) at least some portions of the buried insulating structure 200 by covering the upper surface of the buried insulating structure 200 and/or portions of the side surfaces of the buried insulating structure 200. In other words, the gate structures GS may extend around (e.g., surround) at least some portions of the channel patterns NS and the buried insulating structure 200.

Accordingly, one side surfaces (the first side surfaces) of the channel patterns NS and the lower surface and upper surfaces of the channel patterns NS may abut (e.g., may be) on the gate structures GS, respectively. The other side surfaces (also referred to as second side surfaces or the opposite side surfaces) of the channel patterns NS may abut (e.g., may be) on the buried insulating structure 200. For example, the first side surfaces of the channel patterns NS may face the gate structures GS, and the second side surfaces (the opposite side surfaces) of the channel patterns NS may face the buried insulating structure 200.

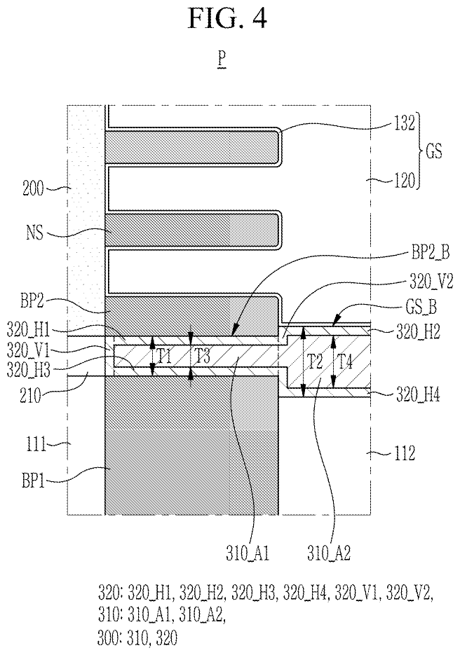

The gate structures GS may be located on the protective layer 300 to be described below. For example, the gate structures GS may be located on the portions of the protective layer 300 overlapping the second field insulating layer 112 in the third direction D3. A lower surface of the gate structures GS (see reference symbol ‘GS_B’ in FIG. 4) may abut (e.g., may be) on the protective layer 300. The lower surface of the gate structures GS (see reference symbol ‘GS_B’ in FIG. 4) may be located at a height level higher than that of a lower surface of the second lower patterns BP2. In other words, the lower surface of the gate structures GS (see reference symbol ‘GS_B’ in FIG. 4) may be located farther from the upper surface of the substrate 100 than the lower surface of the second lower patterns BP2.

Each of the gate structure GS may include a plurality of sub gate structures and a main gate structure. The plurality of sub gate structures may be located between channel patterns NS adjacent to each other in the third direction D3. The main gate structure may be located on the uppermost channel pattern NS.

Each of the active patterns AP may include a plurality of channel patterns NS, and each of the gate structures GS may include a plurality of sub gate structures. The number of the plurality of sub gate structures may be proportional to the number of channel patterns NS included in the active patterns AP. For example, the number of the plurality of sub gate structures may be the same as the number of channel patterns NS. As an example, as shown in FIGS. 2A and 2C, the number of the plurality of sub gate structures of the gate structures GS may be three. However, the number of the plurality of sub gate structures of the gate structures GS is not limited thereto, and four or more sub gate structures may be included.

The plurality of sub gate structures may be located between an upper surface of a channel pattern among the channel patterns NS and a lower surface of another channel pattern among the channel patterns NS facing each other in the third direction D3. The plurality of sub gate structures may be respectively located between an upper surface of the second lower patterns BP2 and a lower surface of lowermost channel patterns NS facing each other in the third direction D3. The plurality of sub gate structures may be adjacent to the source/drain patterns 150 to be described below.

The main gate structures may be located on the plurality of sub gate structures and the channel patterns NS. The main gate structures may be located on the upper surface of (the uppermost channel pattern among) the channel patterns NS.

Referring to FIG. 3A additionally, the gate structures GS may each include a gate insulating layer 132 and a gate electrode 120 sequentially stacked on a channel pattern among the channel patterns NS.

The gate electrode 120 may be located on the second lower patterns BP2. The gate electrode 120 may intersect with the second lower patterns BP2.

The gate electrode 120 may extend around (e.g., surround or cover) at least some portions of the individual channel patterns among the channel patterns NS. The gate electrode 120 may extend around (e.g., surround or cover) at least some portions of the buried insulating structure 200. For example, the gate electrode 120 may extend around (e.g., surround) at least some portions of the channel patterns NS by covering one side surfaces (e.g., the first side surfaces) of the channel patterns NS and the lower surfaces and upper surfaces of the channel patterns NS. Accordingly, three surfaces of each channel pattern NS may be surrounded by the gate electrode 120. Also, the gate structures GS (e.g., the gate electrode 120) may surround at least some portions of the buried insulating structure 200 by covering the upper surface of the buried insulating structure 200 and/or some portions of the side surfaces of buried insulating structure 200. In other words, the gate structures GS (e.g., the gate electrode 120) may extend around (e.g., surround) at least some portions of the channel patterns NS and the buried insulating structure 200.

The gate electrode 120 may be located between the source/drain patterns 150. On both sides of each gate electrode 120 in the first direction D1, source/drain patterns 150 may be located.

The gate electrode 120 may contain, for example, metals, metal alloys, conductive metal nitrides, metal silicides, doped semiconductor materials, conductive metal oxides, and/or conductive metal oxynitrides. The gate electrode 120 may contain, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof, but is not limited thereto. The conductive metal oxides and the conductive metal oxynitrides may include the oxides of the above-mentioned materials, but are not limited thereto.

The gate insulating layers 132 may be located (e.g., may extend) along at least some portions of the perimeters of the channel patterns NS. The gate insulating layers 132 may be in direct contact with the second lower patterns BP2, the source/drain patterns 150, and the channel patterns NS. Although not shown in the drawings, the gate insulating layers 132 may not extend along the side surfaces of gate spacers 140 to be described below. The gate insulating layers 132 may contain, for example, silicon oxide (SiO₂) and/or a high-dielectric constant material. However, the gate insulating layers 132 are not limited thereto, and may extend along the side surfaces of the gate spacers 140.

Each gate insulating layer 132 of the semiconductor device according to some embodiments may include a plurality of layers. Each gate insulating layer 132 may include a layer formed of silicon oxide (SiO₂) and a layer formed of a material having a dielectric constant higher than that of silicon oxide (SiO₂). For example, the material having a dielectric constant higher than that of silicon oxide (SiO₂) may be hafnium oxide (HfO), aluminum oxide (AlO), or tantalum oxide (TaO). In this case, the layers formed of silicon oxide (SiO₂) may be in contact with the channel patterns NS, and the layers formed of the material having the dielectric constant higher than that of the silicon oxide (SiO₂) may be in contact with the gate electrode 120.

The semiconductor device according to some embodiments may further include the gate spacers 140.

The gate spacers 140 may be located on the side surfaces of the gate structures GS. For example, the gate spacers 140 may be located between the gate structures GS and interlayer insulating layers 190

Also, as an example, the gate spacers 140 may be located between the source/drain patterns 150 and the gate structures GS.

The gate spacers 140 may not be located between the second lower patterns BP2 and the channel patterns NS. The gate spacers 140 may not be located between channel patterns NS adjacent to each other in the third direction D3. However, the gate spacers 140 are not limited thereto, and may be located between channel patterns NS adjacent to each other in the third direction D3, or between the second lower patterns BP2 and the channel patterns NS adjacent to each other in the third direction D3.

The gate spacers 140 may include first gate spacers 141 and second gate spacers 142. The first gate spacers 141 may be located on the side surfaces of the gate structures GS. The first gate spacers 141 may be located between the gate structures GS and the second gate spacers 142. The second gate spacers 142 may be located on the side surfaces of the first gate spacers 141. The second gate spacers 142 may be located between the first gate spacers 141 and the interlayer insulating layers 190.

The gate spacers 140 may contain the same material as that in the protective layer 300. For example, the first gate spacers 141 may contain the same material as that in the protective liner 320, and the second gate spacers 142 may contain the same material as that in protective insulating layer 310. For example, the first gate spacers 141 may contain silicon nitride (SiN), and the second gate spacers 142 may contain silicon oxycarbonitride (SiOCN). However, the first gate spacers 141 and the second gate spacers 142 are not limited thereto, and may each contain, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and/or combinations thereof. The gate spacers 140 are shown as double-layers in the drawings; however, this is merely for ease of explanation, and the gate spacers 140 are not limited thereto.

The source/drain patterns 150 may be located on the lower patterns BP. For example, the source/drain patterns 150 may be located on the second lower patterns BP2. On both sides of each gate structure GS, source/drain patterns 150 may be located. Accordingly, the source/drain patterns 150 may be in contact with the side surfaces of the channel patterns NS. The source/drain patterns 150 may be coupled to the channel patterns NS.

The source/drain patterns 150 may be located in source/drain recesses 150R having a depth in the third direction D3. The source/drain patterns 150 may, at least partially, fill the source/drain recesses 150R. Lower surfaces of the source/drain recesses 150R may be defined by the second lower patterns BP2. Side surfaces of the source/drain recesses 150R may be defined by the gate structures GS.

As seen in a cross-sectional view, an upper surface of the source/drain patterns 150 may be located at a height level higher than that of the upper surface of the channel patterns NS (e.g., the upper surface of the uppermost channel pattern NS among from the channel patterns NS). In other words, the upper surface of the source/drain patterns 150 may be located farther from the upper surface of the substrate 100 than the upper surface of the channel patterns NS is. Also, the source/drain patterns 150 may protrude further in the second direction D2 than the channel patterns NS do.

As shown in FIG. 3A, outer surfaces of the source/drain patterns 150 may abut (e.g., may be) on the channel patterns NS, the gate insulating layers 132, and the second lower patterns BP2. The outer surfaces of source/drain patterns 150 may be uneven curved surfaces. For example, portions of the outer surfaces of the source/drain patterns 150 abutting on (e.g., on) the channel patterns NS may have a concave or approximately flat shape as seen in a cross-sectional view. Portions of the outer surfaces of the source/drain patterns 150 abutting (e.g., on) the gate insulating layers 132 may have a concave shape. After the source/drain recesses 150R are formed, a process of selectively etching dummy gate structures may be further performed, whereby the shape of the source/drain recesses 150R may get uneven. In this way, the shape of the outer surfaces of the source/drain patterns 150 may be determined.

The source/drain patterns 150 may be epitaxial patterns formed by a selective epitaxial growth process using the active patterns AP as seeds. The channel patterns NS may be portions of the active patterns AP extending between the source/drain patterns 150. The source/drain patterns 150 may serve as the sources and drains of transistors using the channel patterns NS as channel regions.

The source/drain patterns 150 may contain, for example, silicon (Si) and/or silicon germanium (SiGe). Each source/drain pattern 150 may include multiple layers having different germanium (Ge) concentrations, respectively.

The semiconductor device according to some embodiments may further include the interlayer insulating layers 190. The interlayer insulating layers 190 may be located on the source/drain patterns 150. The interlayer insulating layers 190 may not cover the upper surface of the gate structures GS. The interlayer insulating layers 190 may be located between the side surfaces of the gate structures GS. The interlayer insulating layers 190 may extend around (e.g., surround) the source/drain patterns 150.

The interlayer insulating layers 190 may contain, for example, silicon oxide (SiO₂), silicon nitride (SiN), silicon oxynitride (SiON), and/or low-dielectric constant materials. The low-dielectric constant materials may contain, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, and/or combinations thereof, but are not limited thereto.

The semiconductor device according to some embodiments may further include the gate capping layers 160. The gate capping layers 160 may be located on the gate structures GS. An upper surface of the gate capping layers 160 may be located in the same plane together with an upper surface of the interlayer insulating layers 190 and an upper surface of etch stop films 185. The gate capping layers 160 may be located between the side surfaces of the interlayer insulating layers 190. The gate capping layers 160 may contain, for example, silicon nitride (SiN), silicon oxynitride (SiON), silicon (Si), silicon carbonitride (SiCN), silicon oxycarbonitride (SiOCN), and/or combinations thereof. The gate capping layers 160 may be located on the gate structures GS and the gate spacers 140. The gate capping layers 160 may contain a material having etch selectivity to the interlayer insulating layers 190.

Further, the etch stop films 185 may be located between the interlayer insulating layers 190 and the source/drain patterns 150 and between the interlayer insulating layers 190 and the gate spacers 140 in the semiconductor device according to some embodiments. The etch stop films 185 may be located on the side surfaces of the gate spacers 140 and on the upper surface of the source/drain patterns 150. Also, the etch stop films 185 may extend around (e.g., surround) at least some portions of the source/drain patterns 150.

The etch stop films 185 may contain a material having etch selectivity to the interlayer insulating layers 190. Also, the etch stop films 185 may contain a material having etch selectivity to the source/drain patterns 150 to be described below. The etch stop films 185 may contain, for example, silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and/or combinations thereof.

The semiconductor device according to some embodiments may further include an upper insulating layer 195.

The upper insulating layer 195 may be located on the upper surface of the interlayer insulating layers 190, the upper surface of the etch stop films 185, and the upper surface of the gate capping layers 160.

Although not shown in the drawings, the semiconductor device according to some embodiments may further include contact electrodes.

The contact electrodes may be located on the gate structures GS. The contact electrodes may pass through the upper insulating layer 195 and the gate capping layers 160 so as to be electrically connected (e.g., electrically coupled) to the gate structures GS. In some embodiments, a lower surface of the contact electrodes may be surrounded by the gate structures GS. The lower surface of the contact electrodes may be located at a height level lower than that of the upper surface of the gate structures GS. The contact electrodes may be located on one side and/or the other side (e.g., the opposite side) of each buried insulating structure 200. In some embodiments, the contact electrodes may be located on the gate structures GS and the buried insulating structure 200. The lower surface of the contact electrodes may be surrounded by the gate structure GS and the buried insulating structure 200.

The contact electrodes may contain a conductive material. The contact electrodes may contain, for example, metals, metal alloys, conductive metal nitrides, conductive metal carbides, conductive metal oxides, conductive metal carbonitrides, and/or two-dimensional (2D) materials.

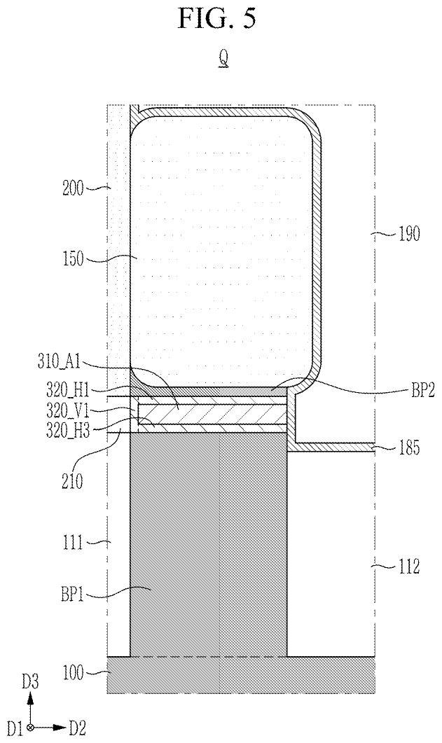

Hereinafter, the protective layer 300 of the semiconductor device according to some embodiments will be described while referring to FIG. 4 and FIG. 5 additionally.

FIG. 4 is an enlarged cross-sectional view of region P in FIG. 2C. FIG. 5 is an enlarged cross-sectional view of region Q in FIG. 2D.

Referring to FIG. 4 and FIG. 5 additionally, as described above, the protective layer 300 may be located on the second field insulating layer 112. The protective layer 300 may extend in the first direction D1. The protective layer 300 may be located between the first lower patterns BP1 and the second lower patterns BP2 and between the gate structures GS and the second field insulating layer 112.

The protective layer 300 may be located in recesses 300R extending in the second direction D2. The protective layer 300 may fill the recesses 300R. Inner surfaces of the recesses 30CR may be defined by insulating patterns. For example, lower surfaces of the recesses 30CR may be defined by the upper surface of the first lower patterns BP1 and the upper surface of the second field insulating layer 112. Upper surfaces of the recesses 30CR may be defined by lower surfaces BP2_B of the second lower patterns BP2 and lower surfaces GS_B of the gate structures GS.

The recesses 300R may have steps having different height levels. For example, the lower surfaces of first portions of the recesses 30CR which are defined by the first lower patterns BP1 may be located at a height level higher than that of the lower surfaces of second portions of the recesses 30CR which are defined by the second field insulating layer 112. Also, the upper surfaces of the first portions of the recesses 30CR which are defined by the second lower patterns BP2 may be located at a height level lower than that of the upper surfaces of the second portions of the recesses 30CR which are defined by the gate structures GS.

Accordingly, the thickness of the first portions of the protective layer 300 located between the first lower patterns BP1 and the second lower patterns BP2 may be smaller than the thickness of the second portions of the protective layer 300 located between the second field insulating layer 112 and the gate structures GS. In other words, the upper surface of the protective layer 300 located between the second field insulating layer 112 and the gate structures GS may be located farther from the upper surface of the substrate 100 than the lower surfaces BP2_B of the second lower patterns BP2 are. The lower surface of the protective layer 300 located between the second field insulating layer 112 and the gate structures GS may be located closer to the upper surface of the substrate 100 than the upper surfaces of the first lower patterns BP1 are. Therefore, the distance in the third direction D3 between the second lower patterns BP2 and the first lower patterns BP1 may be smaller than the distance in the third direction D3 between the gate structures GS and the second field insulating layer 112.

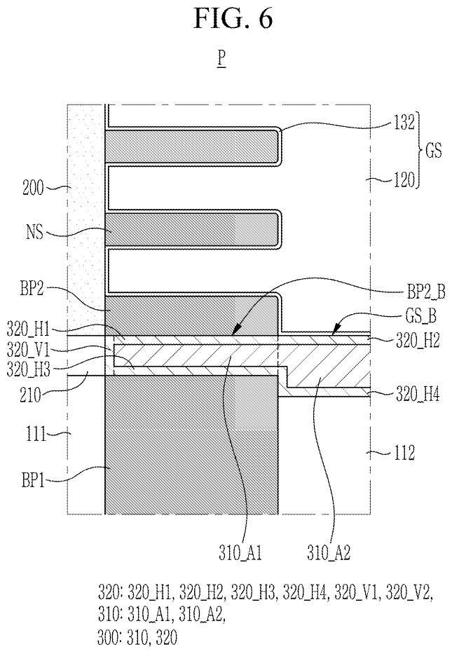

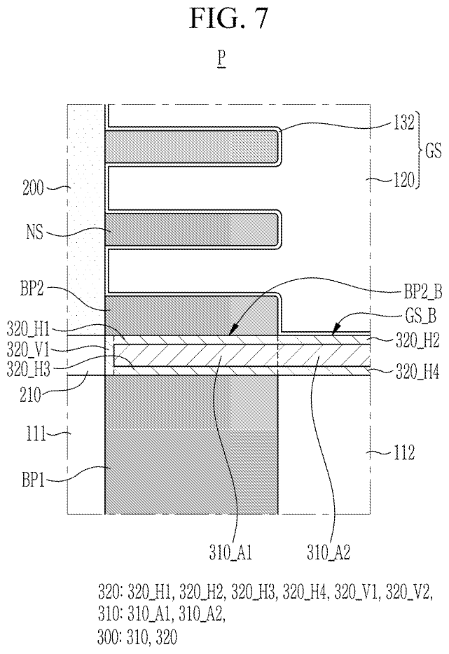

However, the present invention is not limited thereto, and the thickness of the first portions of the protective layer 300 located between the first lower patterns BP1 and the second lower patterns BP2 may be substantially equal to the thickness of the second portions of the protective layer 300 located between the second field insulating layer 112 and the gate structures GS. This will be described below with reference to FIG. 6 and FIG. 7.

The protective layer 300 may include the protective insulating layer 310 and the protective liner 320.

The protective insulating layer 310 may be located on the second field insulating layer 112. The protective insulating layer 310 may be located on the second lower patterns BP2. The protective insulating layer 310 may be located in the recesses 300R extending in the second direction D2. The protective insulating layer 310 may, at least partially, fill the recesses 30CR formed between the first lower patterns BP1 and the second lower patterns BP2 and between the gate structures GS and the second field insulating layer 112. The protective insulating layer 310 may extend in the first direction D1.

The protective insulating layer 310 may include first part 310_A1 located in the recesses 300R between the first lower patterns BP1 and the second lower patterns BP2, and second part 310_A2 located in the recesses 300R between the second field insulating layer 112 and the gate structures GS. Specifically, the first part 310_A1 of the protective insulating layer 310 may be located between the upper surface of the first lower patterns BP1 and the lower surface BP2_B of the second lower patterns BP2. The second part 310_A2 of the protective insulating layer 310 may be located between the upper surface of the second field insulating layer 112 and the lower surface GS_B of the gate structures GS. The first part 310_A1 and the second part 310_A2 may be in contact with each other without any interfaces so as to be integrated. For example, the first part 310_A1 and the second part 310_A1 may comprise a unitary structure. A unitary structure herein may refer to a structure without a visible boundary or interface between two or more sub-elements thereof. A unitary structure may be manufactured by the same process or the same series of processes.

Here, the first part 310_A1 of the protective insulating layer 310 may be portions of the protective insulating layer 310 overlapping the first lower patterns BP1 in the third direction D3, and the second part 310_A2 of the protective insulating layer 310 may be portions of the protective insulating layer 310 overlapping the second field insulating layer 112 in the third direction D3.

The first part 310_A1 of the protective insulating layer 310 may be located between the first lower patterns BP1 and the second lower patterns BP2. The first part 310_A1 may extend in the first direction D1. The first part 310_A1 may overlap the second lower patterns BP2 and the first lower patterns BP1 in the third direction D3. The first part 310_A1 may overlap the source/drain patterns 150 in the third direction D3.

The second part 310_A2 of the protective insulating layer 310 may be located between the second field insulating layer 112 and the gate structures GS. The second part 310_A2 may extend in the second direction D2 from the first part 310_A1 of the protective insulating layer 310. The second part 310_A2 may overlap the second field insulating layer 112 and the gate structures GS in the third direction D3. The second part 310_A2 may not overlap the source/drain patterns 150 in the third direction D3, but is not limited thereto. The second part 310_A2 may not be located between the second field insulating layer 112 and the interlayer insulating layers 190 as shown in FIG. 5, but is not limited thereto.

The second part 310_A2 may include some portions (first portions) overlapping second horizontal part 320_H2 of the protective liner 320 (to be described below) in the third direction D3, and the other portions (second portions) overlapping second vertical parts 320_V2 of the protective liner 320 (to be described below) in the third direction D3. Therefore, the second part 310_A2 may include a thickness of some portions (the first portions) overlapping the second horizontal part 320_H2 of the protective liner 320 in the third direction D3 (for example, a fourth thickness T4), and a thickness of the other portions (the second portions) overlapping the second vertical parts 320_V2 of the protective liner 320 in the third direction D3. The thickness of the other portions (the second portions) overlapping second vertical parts 320_V2 of the protective liner 320 in the third direction D3 may be substantially equal to a thickness of the first part 310_A1 in the third direction D3.

Hereinafter, for ease of explanation, the thickness of the second part 310_A2 in the third direction D3 will be defined as the thickness of the second part 310_A2 overlapping the second horizontal part 320_H2 in the third direction D3.

A third thickness T3 of the first part 310_A1 in the third direction D3 may be smaller than a fourth thickness T4 of the second part 310_A2 in the third direction D3. However, the present invention is not limited thereto, and the third thickness T3 of the first part 310_A1 in the third direction D3 may be substantially equal to the fourth thickness T4 of the second part 310_A2 in the third direction D3. This will be described below with reference to the embodiment in FIG. 6 and FIG. 7.

The first portions of the protective layer 300 (including corresponding portions of the protective insulating layer 310 and corresponding portions of the protective liner 320) located between the first lower patterns BP1 and the second lower patterns BP2 may have a first thickness T1 in the third direction D3. The second portions of the protective layer 300 (including corresponding portions of the protective insulating layer 310 and corresponding portions of the protective liner 320) located between the second field insulating layer 112 and the gate structures GS may have the second thickness T2 in the third direction D3. The first thickness T1 may be smaller than the second thickness T2. However, the present invention is not limited thereto, and the first thickness T1 and the second thickness T2 may be substantially equal to each other. In some embodiments, the first thickness T1 may be smaller than the third thickness T3, and the second thickness T2 may be smaller than the fourth thickness T4.

The upper surface of the first part 310_A1 may be located at a height level lower than an upper surface of the second part 310_A2. In other words, the upper surface of the first part 310_A1 may be located closer to the upper surface of the substrate 100 than the upper surface of the second part 310_A2 is. Therefore, the upper surface of the second part 310_A2 may be located at a height level higher than that of the first part 310_A1 and the lower surface BP2_B of the second lower patterns BP2. Also, the upper surface of the first part 310_A1 may be located at a height level lower than that of the lower surface GS_B of the gate structures GS adjacent to (e.g., on) the second part 310_A2.

The lower surface of the first part 310_A1 may be located at a higher level higher than that of the lower surface of the second part 310_A2. In other words, the lower surface of the first part 310_A1 may be located farther from the upper surface of the substrate 100 than the lower surface of the second part 310_A2 is. Therefore, the lower surface of the second part 310_A2 may be located at a height level lower than that of the upper surface of the first lower patterns BP1 adjacent to (e.g., on) the first part 310_A1. Also, the lower surface of the first part 310_A1 may be located at a height level higher than that of the upper surface of the second field insulating layer 112 adjacent to (e.g., on) the second part 310_A2.

The first part 310_A1 and the second part 310_A2 of the protective insulating layer 310 may contain silicon oxycarbonitride (SiOCN). However, the first part 310_A1 and the second part 310_A2 of the protective insulating layer 310 are not limited thereto, and may contain, for example, silicon oxynitride (SiON), silicon oxycarbonitride (SiOCN), silicon boron nitride (SiBN), silicon oxyboron nitride (SiOBN), silicon oxycarbide (SiOC), and/or combinations thereof.

The protective liner 320 may be located on the protective insulating layer 310 in the recesses 300R. For example, the protective liner 320 may be located on the lower surface, side surfaces, and upper surface of the protective insulating layer 310 in the recesses 300R. In other words, the protective liner 320 may be located between the protective insulating layer 310 and the second lower patterns BP2, between the protective insulating layer 310 and the first lower patterns BP1, between the protective insulating layer 310 and the insulating patterns 210, between the protective insulating layer 310 and the gate structures GS, and between the protective insulating layer 310 and the second field insulating layer 112. The protective liner 320 may extend in a constant thickness along the profiles of the recesses 300R. As described above, the recesses 300R may have steps, whereby the protective liner 320 may have curved (or stepped) portions. The protective liner 320 may extend in the first direction D1.

The protective liner 320 may include first to fourth horizontal parts 320_H1 to 320_H4, first vertical parts 320_V1, and the second vertical parts 320_V2. The first to fourth horizontal part 320_H1 to 320_H4 of the protective liner 320 may be in contact with the first vertical parts 320_V1 and the second vertical parts 320_V2 without any interfaces, so as to be integrated. For example, the first to fourth horizontal parts 320_H1 to 320_H4, the first vertical part 320_V1, and the second vertical part 320_V2 may comprise a unitary structure.

The first horizontal part 320_H1 may extend along the upper surface of the first part 310_A1 of the protective insulating layer 310. The first horizontal part 320_H1 may extend in a constant thickness along the upper surface of the first part 310_A1 of the protective insulating layer 310. The first horizontal part 320_H1 may be located between the first part 310_A1 of the protective insulating layer 310 and the second lower patterns BP2. Specifically, the first horizontal part 320_H1 may be located between the upper surface of the first part 310_A1 of the protective insulating layer 310 and the lower surface BP2_B of the second lower patterns BP2. The first horizontal part 320_H1 may overlap the second lower patterns BP2 in the third direction D3. Also, the first horizontal part 320_H1 may overlap the first lower patterns BP1 in the third direction D3. An upper surface of the first horizontal part 320_H1 may abut (e.g., may be) on the second lower patterns BP2. A lower surface of the first horizontal part 320_H1 may abut (e.g., may be) on the protective insulating layer 310.

The first horizontal part 320_H1 may extend in the first direction D1 as shown in FIG. 2A. The first horizontal part 320_H1 may overlap the source/drain patterns 150 in the third direction D3.

The second horizontal part 320_H2 may extend along the upper surface of the second part 310_A2 of the protective insulating layer 310. The second horizontal part 320_H2 may extend in a constant thickness along the upper surface of the second part 310_A2 of the protective insulating layer 310. The second horizontal part 320_H2 may be located between the second part 310_A2 of the protective insulating layer 310 and the gate structures GS. Specifically, the second horizontal part 320_H2 may be located between the upper surface of the second part 310_A2 of the protective insulating layer 310 and the lower surface GS_B of the gate structures GS. The second horizontal part 320_H2 may overlap the gate structures GS in the third direction D3. Also, the second horizontal part 320_H2 may overlap the second field insulating layer 112 in the third direction D3. The upper surface of the second horizontal part 320_H2 may abut (e.g., may be) on the gate structures GS. The lower surface of the second horizontal part 320_H2 may abut (e.g., may be) on the protective insulating layer 310 (e.g., the second part 310_A2).

The upper surface of the first horizontal part 320_H1 may be located at a height level lower than that of the upper surface of the second horizontal part 320_H2. In other words, the upper surface of the first horizontal part 320_H1 may be located closer to the upper surface of the substrate 100 than the upper surface of the second horizontal part 320_H2 is. Therefore, the upper surface of the second horizontal part 320_H2 may be located at a height level higher than that of the lower surface BP2_B of the second lower patterns BP2 adjacent to (e.g., on) the first horizontal part 320_H1. Also, the upper surface of the first horizontal part 320_H1 may be located at a height level lower than that of the lower surface GS_B of the gate structures GS adjacent to (e.g., on) the second horizontal part 320_H2.

The third horizontal part 320_H3 may extend along a lower surface of the first part 310_A1 of the protective insulating layer 310. The third horizontal part 320_H3 may extend in a constant thickness along the lower surface of the first part 310_A1 of the protective insulating layer 310. The third horizontal part 320_H3 may be located between the first part 310_A1 of the protective insulating layer 310 and the first lower patterns BP1. Specifically, the third horizontal part 320_H3 may be located between the lower surface of the first part 310_A1 of the protective insulating layer 310 and the upper surface of the first lower patterns BP1. The third horizontal part 320_H3 may overlap the second lower patterns BP2 in the third direction D3. Also, the third horizontal part 320_H3 may overlap the first lower patterns BP1 in the third direction D3. The upper surface of the third horizontal part 320_H3 may abut (e.g., may be) on the protective insulating layer 310. The lower surface of the third horizontal part 320_H3 may abut (e.g., may be) on the first lower patterns BP1.

The third horizontal part 320_H3 may extend in the first direction D1 as shown in FIG. 2A. The third horizontal part 320_H3 may overlap the source/drain patterns 150 in the third direction D3.

The fourth horizontal part 320_H4 may extend along the lower surface of the second part 310_A2 of the protective insulating layer 310. The fourth horizontal part 320_H4 may extend in a constant thickness along the lower surface of the second part 310_A2 of the protective insulating layer 310. The fourth horizontal part 320_H4 may be located between the second part 310_A2 of the protective insulating layer 310 and the second field insulating layer 112. Specifically, the fourth horizontal part 320_H4 may be located between the lower surface of the second part 310_A2 of the protective insulating layer 310 and the upper surface of the second field insulating layer 112. The fourth horizontal part 320_H4 may overlap the gate structures GS in the third direction D3. Also, the fourth horizontal part 320_H4 may overlap the second field insulating layer 112 in the third direction D3. The upper surface of the fourth horizontal part 320_H4 may abut (e.g., may be) on the protective insulating layer 310 (e.g., the second part 310_A2). The lower surface of the fourth horizontal part 320_H4 may abut (e.g., may be) on the second field insulating layer 112.

The lower surface of the third horizontal part 320_H3 may be located at a height level higher than that of the lower surface of the fourth horizontal part 320_H4. In other words, the lower surface of the third horizontal part 320_H3 may be located farther from the upper surface of the substrate 100 than the lower surface of the fourth horizontal part 320_H4 is. Therefore, the lower surface of the fourth horizontal part 320_H4 may be located at a height level lower than that of the upper surface of the first lower patterns BP1 adjacent to (e.g., on) the third horizontal part 320_H3. Also, the lower surface of the third horizontal part 320_H3 may be located at a height level higher than that of the upper surface of the second field insulating layer 112 adjacent to (e.g., on) the fourth horizontal part 320_H4.

In FIG. 4, it is shown that the upper surface of the first horizontal part 320_H1 are located at a height level lower than that of the upper surface of the second horizontal part 320_H2, and the lower surface of the third horizontal part 320_H3 are located at a height level higher than the lower surface of the fourth horizontal part 320_H4; however, the present invention is not limited thereto. For example, the upper surface of the first horizontal part 320_H1 and the upper surface of the second horizontal part 320_H2 may be located substantially at the same height level. In some embodiments, the lower surface of the third horizontal part 320_H3 may be located substantially at the same height level as that of the lower surface of the fourth horizontal part 320_H4. This will be described below with reference to FIG. 6.

The distance in the third direction D3 between the first horizontal part 320_H1 and the third horizontal part 320_H3 may be smaller than the distance in the third direction D3 between the second horizontal part 320_H2 and the fourth horizontal part 320_H4. Here, the distance in the third direction D3 between the first horizontal part 320_H1 and the third horizontal part 320_H3 may be substantially equal to the third thickness T3 of the first part 310_A1 of the protective insulating layer 310 interposed between the first horizontal part 320_H1 and the third horizontal part 320_H3. Also, the distance in the third direction D3 between the second horizontal part 320_H2 and the fourth horizontal part 320_H4 may be substantially equal to the fourth thickness T4 of the second part 310_A2 of the protective insulating layer 310 interposed between the second horizontal part 320_H2 and the fourth horizontal part 320_H4. However, the present invention is not limited thereto.

The first thickness T1 from the lower surface of the third horizontal part 320_H3 to the upper surface of the first horizontal part 320_H1 may be smaller than the second thickness T2 from the lower surface of the fourth horizontal part 320_H4 to the upper surface of the second horizontal part 320_H2. Here, the thickness from the lower surface of the third horizontal part 320_H3 to the upper surface of the first horizontal part 320_H1 may be substantially equal to the thickness in the third direction D3 of the protective layer 300 located between the first lower patterns BP1 and the second lower patterns BP2. Also, the thickness from the lower surface of the fourth horizontal part 320_H4 to the upper surface of the second horizontal part 320_H2 may be substantially equal to the thickness in the third direction D3 of the protective layer 300 located between the second field insulating layer 112 and the gate structures GS. However, the present invention is not limited thereto.

The first vertical parts 320_V1 may extend along the side surfaces of the first part 310_A1 of the protective insulating layer 310. The first vertical parts 320_V1 may extend in a constant thickness along the first part 310_A1 of the protective insulating layer 310. The first vertical parts 320_V1 may be located between the insulating patterns 210 and the first part 310_A1 of the protective insulating layer 310. The first vertical parts 320_V1 may overlap the side surfaces of the insulating patterns 210 in the second direction D2. The first vertical parts 320_V1 may abut (e.g., may be) on the insulating patterns 210. The second vertical parts 320_V2 may extend along at least portions of one side surfaces of the second part 310_A2 of the protective insulating layer 310. For example, the second vertical parts 320_V2 may be located between the side surfaces of the first lower patterns BP1 and the second part 310_A2 of the protective insulating layer 310 and between the side surfaces of the second lower patterns BP2 and the second part 310_A2 of the protective insulating layer 310.

The first to fourth horizontal part 320_H1 to 320_H4, the first vertical parts 320_V1, and the second vertical parts 320_V2 of the protective liner 320 may each contain silicon nitride (SiN), but are not limited thereto.

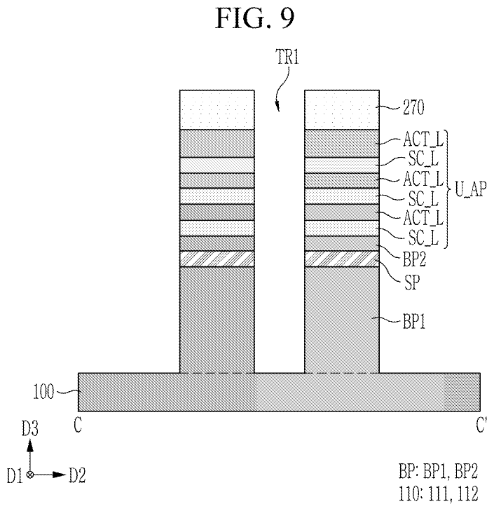

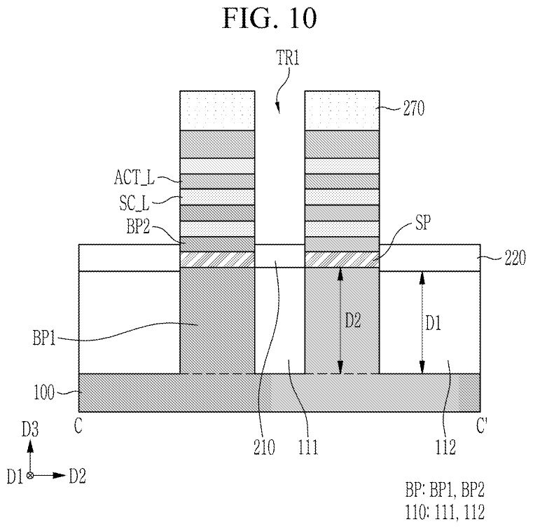

When the semiconductor device, according to some embodiments, is manufactured, in the process of forming the lower patterns BP, sacrificial insulating layers (see reference symbol ‘SP’ in FIG. 9) may be formed, and in the process of forming the field insulating layers 110, sacrificial insulating patterns (see reference symbol ‘220’ in FIG. 10) may be formed. Thereafter, the sacrificial insulating layers SP and the sacrificial insulating patterns 220 may be removed, whereby the protective liner 320 and the protective insulating layer 310 may be individually formed. Therefore, it is possible to prevent the level of the second field insulating layer 112 from lowering in the subsequent processes.

Since the second field insulating layer 112 are protected by the protective liner 320 and the protective insulating layer 310, when the gate structures GS are formed, it may be possible to reduce leakage current occurring between the gate structures GS and the first lower patterns BP1 and between the gate structures GS and the source/drain patterns 150 adjacent thereto. Therefore, the reliability of the semiconductor device may be improved.

Hereinafter, semiconductor devices according to some embodiments will be described with reference to FIG. 6 and FIG. 7.

FIG. 6 and FIG. 7 are enlarged cross-sectional views illustrating a semiconductor device according to some embodiments and corresponding to region P in FIG. 2C.

Embodiments shown in FIG. 6 and FIG. 7 may have a considerable number of parts identical to those in the embodiments shown in FIG. 1 to FIG. 5, so a description of the identical parts may not be made, and the differences will be mainly described. The present embodiments are different from the above embodiments in the shapes of protective layer (e.g., the protective layer 300), and will be described below.

A semiconductor device according to some embodiments may include a substrate 100, active patterns AP located on the substrate 100, field insulating layers 110 located between the active patterns AP, a buried insulating structure 200 located on the field insulating layers 110, gate structures GS extending around (e.g., surrounding) at least some portions of the active patterns AP, source/drain patterns 150 located on both (e.g., opposite) sides of each active pattern AP, and a protective layer 300 located between the field insulating layers 110 and the gate structures GS.

In the above embodiments, the upper surface of the first part 310_A1 may be located at a height level lower than that of the upper surface of the second part 310_A2. In other words, the upper surface of the first part 310_A1 may be located closer to the upper surface of the substrate 100 than the upper surface of the second part 310_A2 is. Also, the lower surface of the first part 310_A1 may be located at a height level higher than that of the lower surface of the second part 310_A2. In other words, the lower surface of the first part 310_A1 may be located farther from the upper surface of the substrate 100 than the lower surface of the second part 310_A2 is.

Referring to FIG. 6, the upper surface of the first part 310_A1 of the protective layer 300 of the semiconductor device according to some embodiments may be located at the substantially same height level as that of the upper surface of the second part 310_A2. In other words, the upper surface of the first part 310_A1 may have substantially the same distance (e.g., height) in the third direction D3 from the upper surface of the substrate 100 as that of the upper surface of the second part 310_A2. Therefore, the upper surface of the second part 310_A2 may be located substantially at the same height level as that of the lower surface BP2_B of the second lower patterns BP2 adjacent to (e.g., on) the first part 310_A1. Also, the upper surface of the first part 310_A1 may be located substantially at the same height level as that of the lower surface GS_B of the gate structures GS adjacent to (e.g., on) the second part 310_A2.

Referring to FIG. 7, the lower surface of the first part 310_A1 of the semiconductor device according to some embodiments may be located at the substantially same height level as that of the lower surface of the second part 310_A2. In other words, the lower surface of the first part 310_A1 may have substantially the same distance (e.g., height) in the third direction D3 from the upper surface of the substrate 100 as that of the lower surface of the second part 310_A2. Therefore, the lower surface of the second part 310_A2 may be located at the substantially same height level as that of the upper surface of the first lower patterns BP1 adjacent to (e.g., on) the first part 310_A1. Also, the lower surface of the first part 310_A1 may be located at the substantially same height level as that of the upper surface of the second field insulating layer 112 adjacent to (e.g., on) the second part 310_A2.

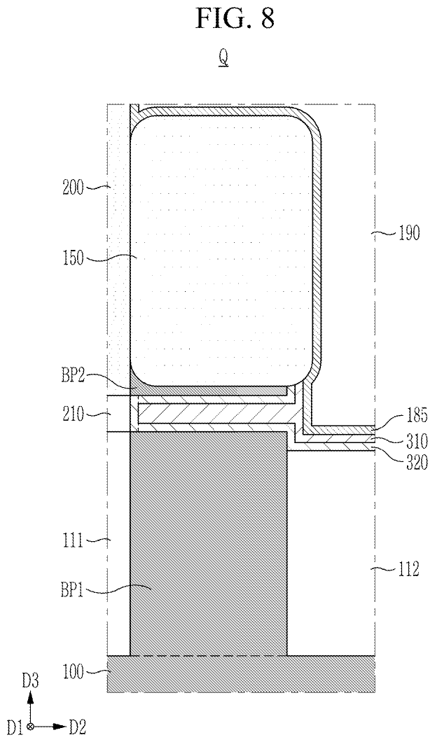

Hereinafter, a semiconductor device according to some embodiments will be described with reference to FIG. 8.

FIG. 8 is an enlarged cross-sectional view illustrating a semiconductor device according to some embodiments and corresponding to region Q in FIG. 2D.

Some embodiments shown in FIG. 8 have a considerable number of portions identical or similar to those in the embodiments shown in FIG. 1 to FIG. 5, so a description of the identical or similar portions may not be made, and the differences will be mainly described. The present embodiments are different from the above embodiments in the shapes of protective layer (e.g., the protective layer 300), and will be described below.

A semiconductor device according to some embodiments may include a substrate 100, active patterns AP located on the substrate 100, field insulating layers 110 located between the active patterns AP, buried insulating structure 200 located on the field insulating layers 110, gate structures GS extending around (e.g., surrounding) at least some portions of the active patterns AP, source/drain patterns 150 located on both sides (e.g., opposite sides) of each active pattern AP, and a protective layer 300 located between the field insulating layers 110 and the gate structures GS.

In the above embodiments, the protective layer 300 may not located between the second field insulating layer 112 and the interlayer insulating layers 190.

Referring to FIG. 8, the protective layer 300 of the semiconductor device according to some embodiments may be located between the second field insulating layer 112 and the interlayer insulating layers 190. The protective layer 300 may include the protective liner 320 and the protective insulating layer 310.

For example, the protective liner 320 may be located between the second field insulating layer 112 and the interlayer insulating layers 190. The protective liner 320 may overlap the interlayer insulating layers 190 in the third direction D3. The protective liner 320 may extend along the side surfaces and lower surface of the second lower patterns BP2, the side surfaces of the insulating patterns 210, the upper surface of the first lower patterns BP1, some portions of the side surfaces of the first lower patterns BP1, and the upper surface of the second field insulating layer 112. The protective liner 320 may be located between the protective insulating layer 310 and the second field insulating layer 112.

The protective insulating layer 310 may be located on the protective liner 320. The protective insulating layer 310 may extend along the profiles of the protective liner 320. The protective insulating layer 310 may be located between the interlayer insulating layers 190 and the protective liner 320. The protective insulating layer 310 may overlap the interlayer insulating layers 190 in the third direction D3.

Hereinafter, a method of manufacturing the buried insulating structure 200 of the semiconductor device according to some embodiments will be described with reference to FIG. 9 to FIG. 12.

FIG. 9 to FIG. 12 are cross-sectional views illustrating intermediate steps of a method of manufacturing a buried insulating structure of the semiconductor device according to some embodiments and corresponding to line C-C′ in FIG. 1.

As shown in FIG. 9, on the substrate 100, the lower patterns BP, the sacrificial insulating layers SP, and channel pattern structures U_AP may be formed. Each channel pattern structure U_AP may include a plurality of gate sacrifice patterns SC_L and a plurality of semiconductor patterns ACT_L alternately stacked.

The substrate 100 may be a silicon-on-insulator (SOI) or bulk silicon. In some embodiments, the substrate 100 may be a silicon substrate, or may contain other materials such as silicon germanium (SiGe), silicon germanium on insulator (SGOI), indium antimonide, a lead tellurium compound, indium arsenide, indium phosphide, gallium arsenide, and/or gallium antimonide, but is not limited thereto.

On the substrate 100, the lower patterns BP (including the first lower patterns BP1 and the second lower patterns BP2 on the first lower patterns BP1) may be located so as to protrude from the upper surface of the substrate 100. The lower patterns BP may protrude from the upper surface of the substrate 100 in the third direction D3. The lower patterns BP may be located so as to be apart from one another in the second direction D2. The lower patterns BP may extend long in the first direction D1.

Between the first lower patterns BP1 and the second lower patterns BP2, the sacrificial insulating layers SP may be located. The sacrificial insulating layers SP may protrude from the upper surface of the first lower patterns BP1 in the third direction D3. The sacrificial insulating layers SP may be located so as to be apart from one another in the second direction D2. The sacrificial insulating layers SP may extend in the first direction D1.

The sacrificial insulating layers SP may contain a material different from that in the lower patterns BP. The sacrificial insulating layers SP may contain a material having etch selectivity to the substrate 100. For example, the sacrificial insulating layers SP may contain silicon germanium (SiGe). In this case, the content of germanium (Ge) in the sacrificial insulating layers SP may be greater than the content of germanium (Ge) in the substrate 100.

The lower patterns BP and the sacrificial insulating layers SP may be formed by first trenches TR1 formed using hard mask patterns 270 (to be described below) as a mask. In this case, the sacrificial insulating layers SP may be insulating layers in the substrate 100 when the substrate 100 consists of a plurality of layers including insulating layers (for example, silicon-on-insulator (SOI) or silicon germanium on insulator (SGOI), etc.). However, the present invention is not limited thereto.

The channel pattern structures U_AP may be located on the second lower patterns BP2. The channel pattern structures U_AP may abut on the second lower patterns BP2.

The plurality of gate sacrifice patterns SC_L and the plurality of semiconductor patterns ACT_L may be sequentially and alternately stacked so as to comprise a channel pattern structure U_AP. Any one gate sacrifice pattern from among the plurality of gate sacrifice patterns SC_L may be located on a second lower pattern BP2, and abut on the second lower pattern BP2. In the drawings, it is shown that three gate sacrifice patterns SC_L and three semiconductor patterns ACT_L are alternately stacked; however, this is merely an example, the numbers of the plurality of gate sacrifice patterns SC_L and the plurality of semiconductor patterns ACT_L may be variously changed. In other words, each of the number of gate sacrifice patterns SC_L which are stacked and the number of semiconductor patterns ACT_L which are stacked may be smaller than 3, or larger than 3.

The channel pattern structures U_AP may be formed using an epitaxial growth method. For example, silicon germanium (SiGe) layers and silicon (Si) layers may be alternately formed by an epitaxial growth method, and the hard mask patterns 270 may be formed thereon. The hard mask patterns 270 may be formed of silicon nitride (SiN). The silicon germanium (SiGe) layers and the silicon layers may be patterned using the hard mask patterns 270 as a mask, such that the first trenches TR1 may be formed.

By the first trenches TR1, the channel pattern structures U_AP may be formed. In this case, the plurality of gate sacrifice patterns SC_L may be formed of silicon germanium (SiGe), and the plurality of semiconductor patterns ACT_L may be formed of silicon (Si). However, the materials of the plurality of gate sacrifice patterns SC_L and the plurality of semiconductor patterns ACT_L are not limited thereto, and may be variously changed.

The plurality of channel pattern structures U_AP may extend in the first direction D1 as seen in a plan view. The plurality of channel pattern structures U_AP may be located on the substrate 100.

As shown in FIG. 10, the field insulating layers 110 may be formed between the plurality of channel pattern structures U_AP.

On the substrate 100 having the lower patterns BP, the sacrificial insulating layers SP, and the channel pattern structures U_AP formed thereon, the field insulating layers 110 may be formed. Specifically, the field insulating layers 110 may include the first field insulating layer 111 located on one side surfaces (e.g., first side surfaces) of the lower patterns BP, and the second field insulating layer 112 located on the other side surfaces (also referred to as opposite side surfaces or second side surfaces) of the lower patterns BP. The first field insulating layer 111 may cover some entire side surfaces (e.g., the first side surfaces) of the lower patterns BP. The second field insulating layer 112 may cover portions of the other side surfaces (e.g., the second side surfaces or the opposite side surfaces) of the lower patterns BP.

The thickness of the first field insulating layer 111 in the third direction D3 may be larger than the thickness of the second field insulating layer 112 in the third direction D3. In other words, the upper surface of the first field insulating layer 111 may be located at a height level higher than that of the upper surface of the second field insulating layer 112. The upper surface of the first field insulating layer 111 may be located farther from the upper surface of the substrate 100 than the upper surface of the second field insulating layer 112 is. However, the present invention is not limited thereto, and the thickness of the first field insulating layer 111 in the third direction D3 may be substantially equal to the thickness of the second field insulating layer 112 in the third direction D3.

The first field insulating layer 111 and the second field insulating layer 112 may be formed of an insulating material capable of filling voids well. Each of the first field insulating layer 111 and the second field insulating layer 112 may contain a material having etch selectivity to the sacrificial insulating patterns 220 to be described below. For example, the field insulating layers 110 may contain silicon oxide (SiO₂) denser than the insulating patterns 210, but are not limited thereto. For example, the field insulating layers 110 may contain silicon nitride (SiN), silicon oxynitride (SiON), or a combination layer thereof. In the drawings, each field insulating layer 110 is shown as a single layer; however, this is merely for ease of explanation, and the field insulating layers 110 are not limited thereto.

However, the present invention is not limited thereto, and the first field insulating layer 111 and the second field insulating layer 112 may be formed by forming a field insulating material to the same height level as that of the upper surface of the hard mask patterns 270 and removing at least some portions of the field insulating material. In this case, the field insulating layers 110 may be formed of a material having etch selectivity different from that of the channel pattern structures U_AP. Therefore, the channel pattern structures U_AP may not be removed in the process of removing at least some portions of the field insulating material.

Subsequently, on the field insulating layers 110, the insulating patterns 210 and the sacrificial insulating patterns 220 may be formed. For example, the insulating patterns 210 may be formed on the first field insulating layer 111, and the sacrificial insulating patterns 220 may be formed on the second field insulating layer 112.

The thickness of the sacrificial insulating patterns 220 in the third direction D3 may be larger than the thickness of the sacrificial insulating layers SP in the third direction D3. The lower surface of the sacrificial insulating patterns 220 may be located at a height level lower than that of the lower surface of the sacrificial insulating layers SP. In other words, the lower surface of the sacrificial insulating patterns 220 may be located closer to the upper surface of the substrate 100 than the lower surface of the sacrificial insulating layers SP is. Also, the upper surface of the sacrificial insulating patterns 220 may be located at a height level higher than that of the upper surface of the sacrificial insulating layers SP. In other words, the upper surface of the sacrificial insulating patterns 220 may be located farther from the upper surface of the substrate 100 than the upper surface of the sacrificial insulating layers SP is. Accordingly, the side surfaces of the sacrificial insulating layers SP may be completely overlapped by the side surfaces of the sacrificial insulating patterns 220.

The insulating patterns 210 and the sacrificial insulating patterns 220 may each contain a material having etch selectivity to the field insulating layers 110. For example, the insulating patterns 210 and the sacrificial insulating patterns 220 may each contain silicon oxide (SiO₂). The sacrificial insulating patterns 220 may contain silicon oxide (SiO₂) less dense than the field insulating layers 110, but are not limited thereto. In other words, when the field insulating layers 110 and the sacrificial insulating patterns 220 each contain silicon oxide (SiO₂), the field insulating layers 110 may contain silicon oxide (SiO₂) denser and solider than silicon oxide (SiO₂) contained in the sacrificial insulating patterns 220.

In this case, the degrees of densification of the materials contained in the field insulating layers 110 and the insulating patterns 210 may be determined depending on the annealing temperatures of silicon oxide (SiO₂), the numbers of times of annealing, etc., in the processes of forming the field insulating layers 110 and the insulating patterns 210. For example, as the number of times of annealing increases, silicon oxide (SiO₂) may become denser.

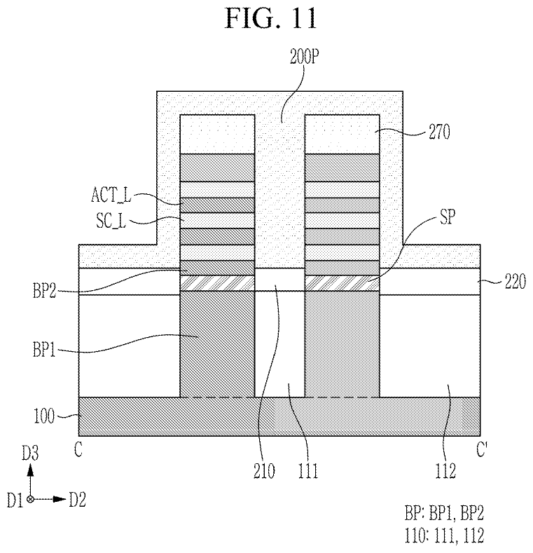

As shown in FIG. 11, a preliminary buried insulating structure 200P may be formed on the sacrificial insulating patterns 220, the insulating patterns 210, and the hard mask patterns 270. The preliminary buried insulating structure 200P may be formed on the surfaces of the sacrificial insulating patterns 220, the insulating patterns 210, the channel pattern structures U_AP, and the hard mask patterns 270 so as to conform to them. The first trenches TR1 may be formed narrowly, whereby the preliminary buried insulating structure 200P may fill the first trenches TR1. For example, the width of the first trenches TR1 may be 15 nanometers (nm) to 25 nm.

The preliminary buried insulating structure 200P may contain a low-dielectric constant material. The preliminary buried insulating structure 200P may contain a material having etch selectivity to the sacrificial insulating patterns 220 and etch selectivity to the semiconductor patterns ACT_L, which are different from each other. The buried insulating structure 200 may contain, for example, silicon nitride (SiN), silicon carbonitride (SiCN), silicon oxycarbide (SiOC), and/or low-dielectric constant materials, but are not limited thereto.

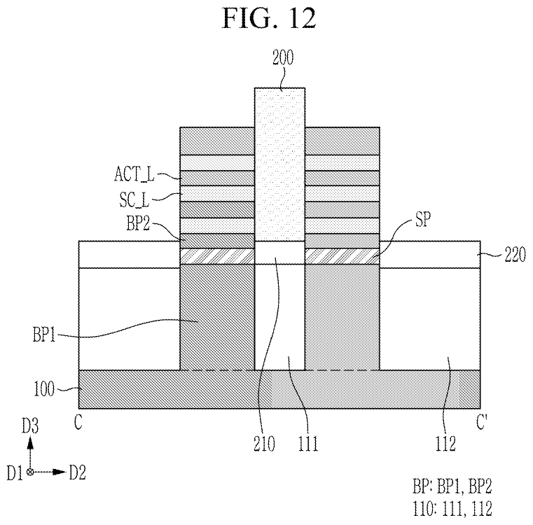

As shown in FIG. 12, some portions of the preliminary buried insulating structure 200P may be removed by performing an etching process, whereby the buried insulating structure 200 may be formed. The etching process may be performed in a dry or wet etching manner, but is not limited thereto. As described above, the preliminary buried insulating structure 200P may contain a material having etch selectivity to the sacrificial insulating patterns 220 and the channel pattern structures U_AP. Therefore, as the preliminary buried insulating structure 200P is etched, although the side surfaces of the channel pattern structures U_AP and the upper surface of the sacrificial insulating patterns 220 are exposed, the side surfaces of the channel pattern structures U_AP and the upper surface of the sacrificial insulating patterns 220 may not be removed.

The preliminary buried insulating structure 200P may be etched to the upper surface of the hard mask patterns 270. Accordingly, the hard mask patterns 270 and the sacrificial insulating patterns 220 may be exposed, and the buried insulating structure 200 may be formed. Subsequently, the hard mask patterns 270 may be removed.

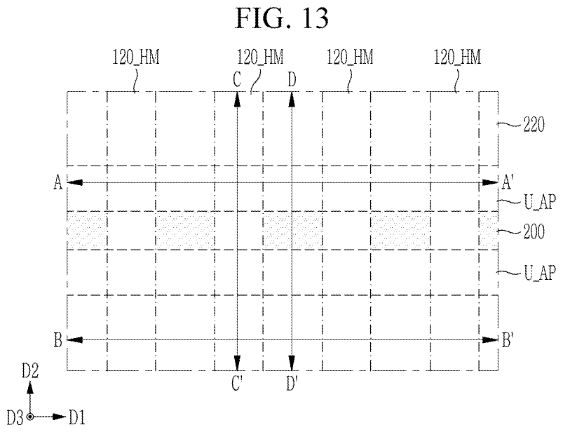

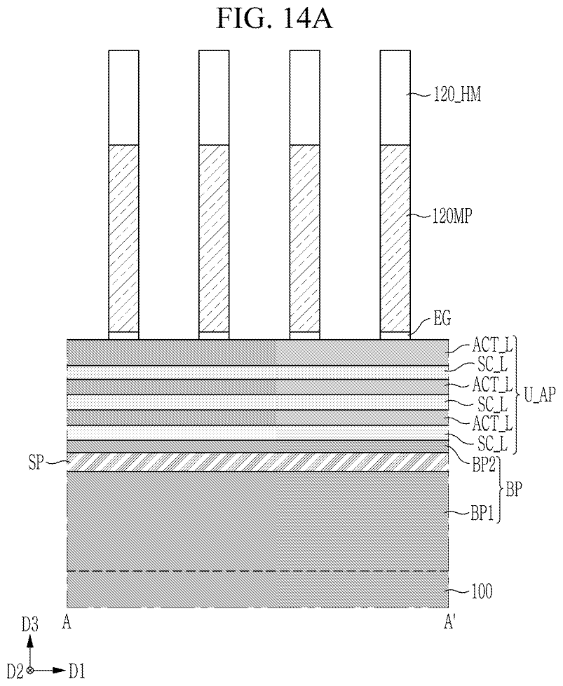

Now, a method of manufacturing the semiconductor device according to some embodiments will be described with reference to FIG. 13 to FIG. 32D.

FIG. 13, FIG. 15, FIG. 17, FIG. 19, FIG. 21, FIG. 23, FIG. 25, FIG. 27, FIG. 29, and FIG. 31 are plan views illustrating intermediate steps of a method of manufacturing the semiconductor device according to some embodiments.

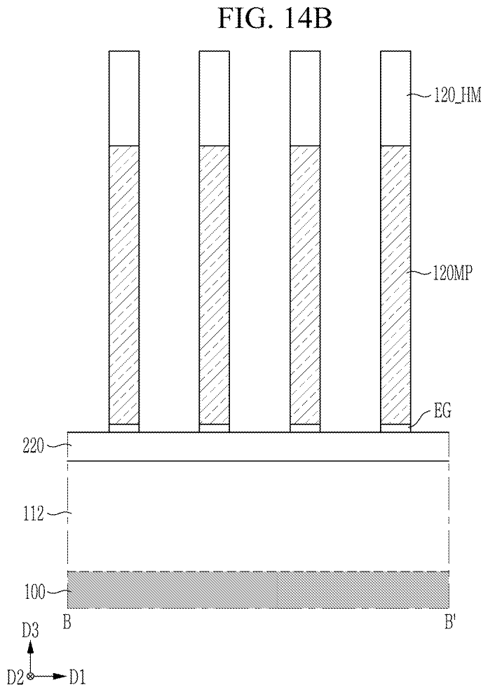

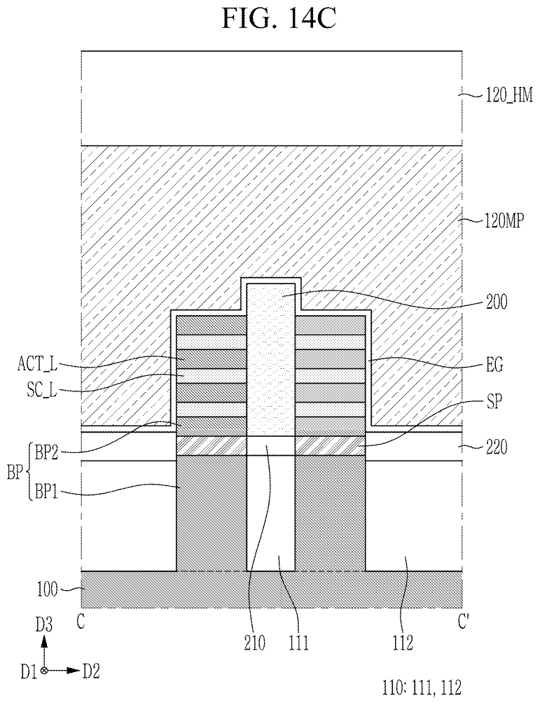

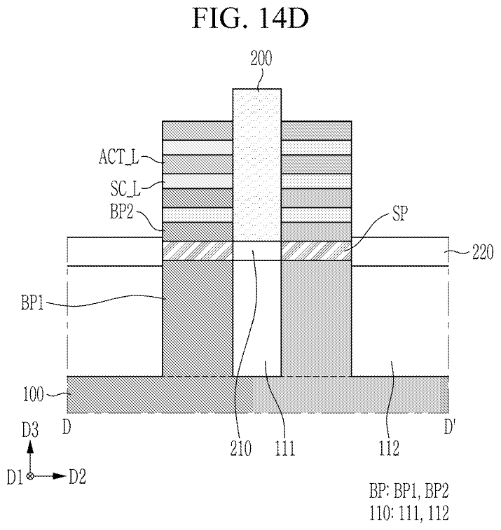

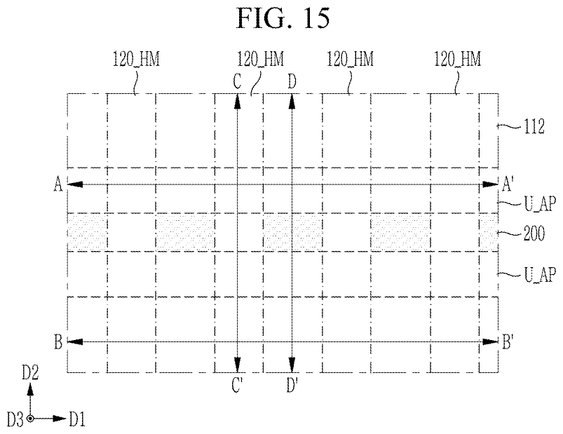

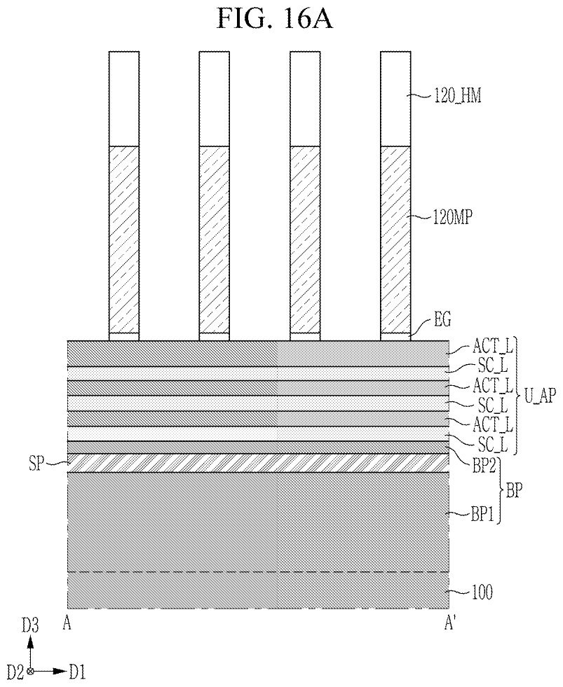

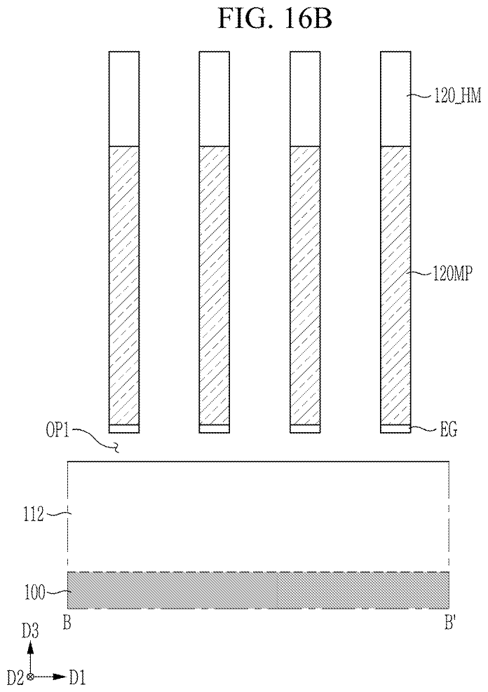

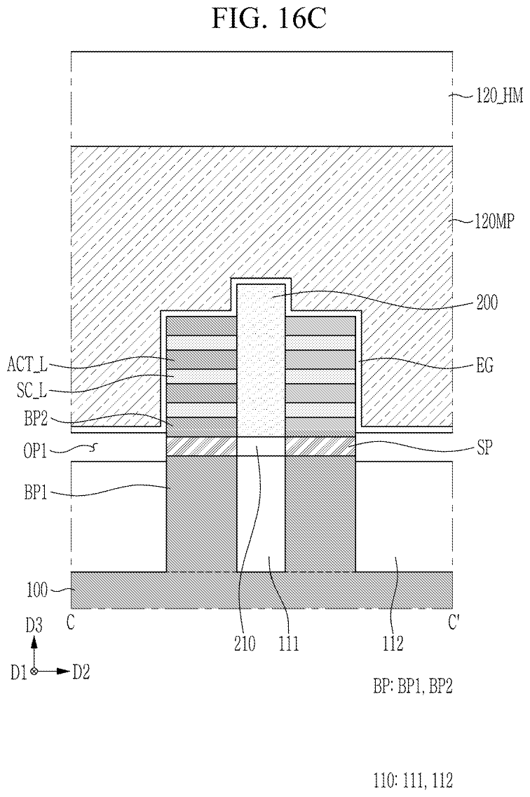

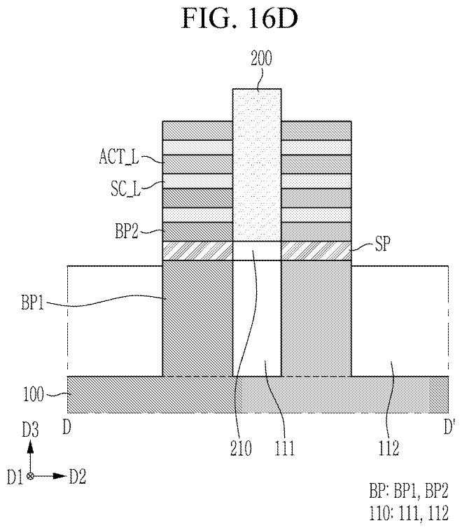

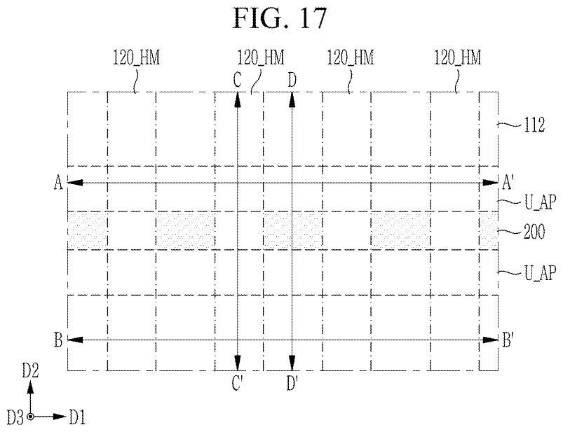

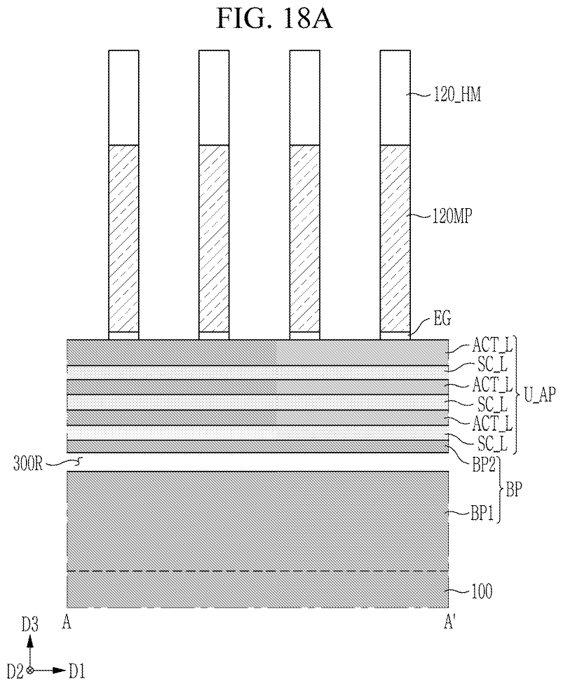

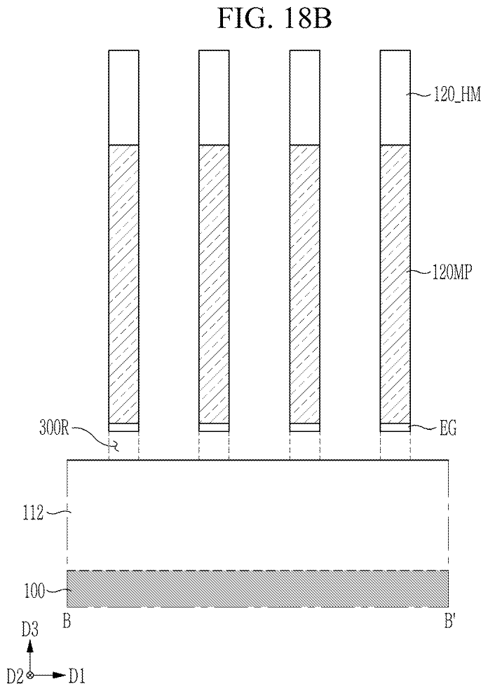

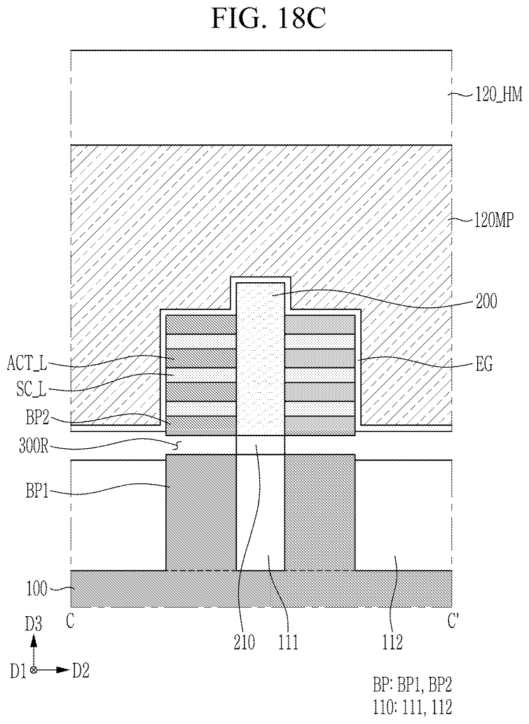

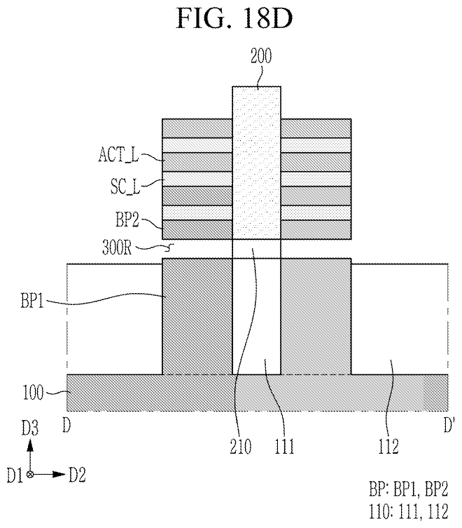

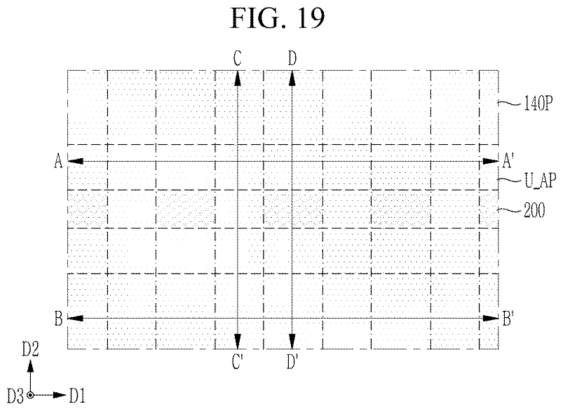

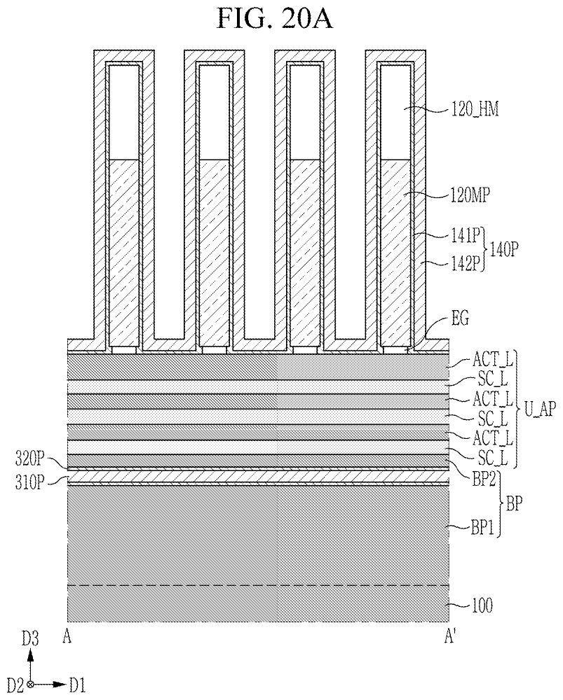

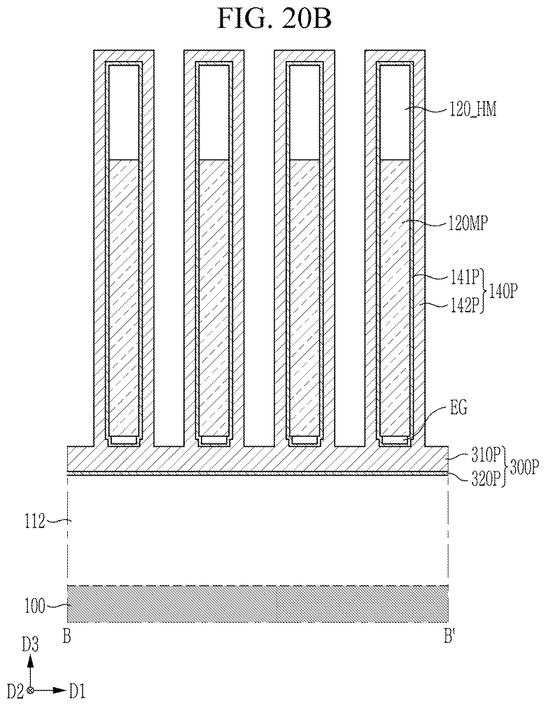

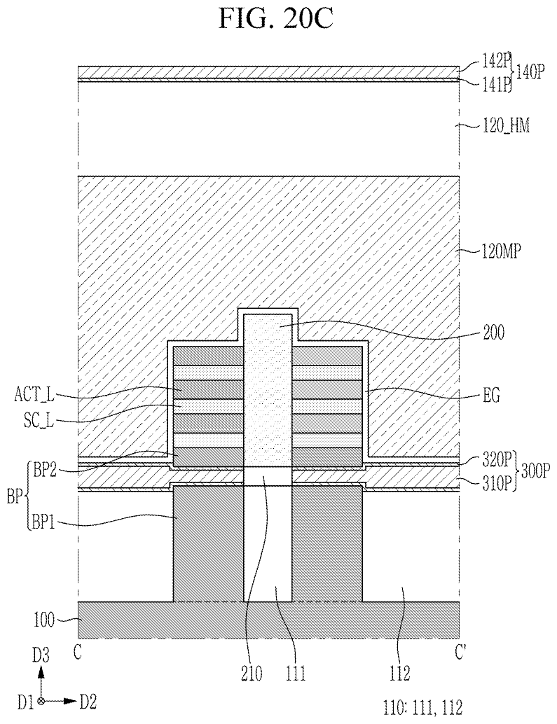

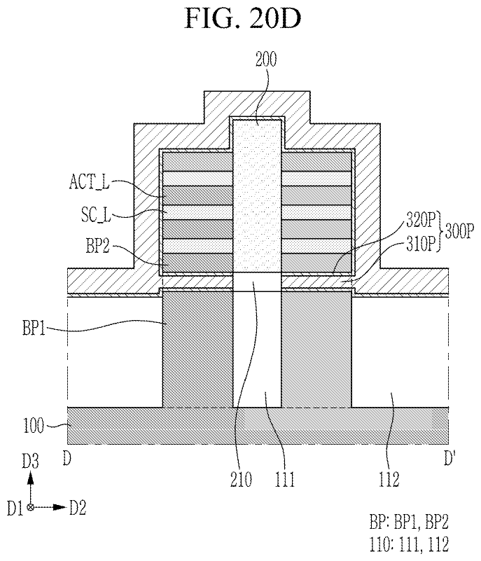

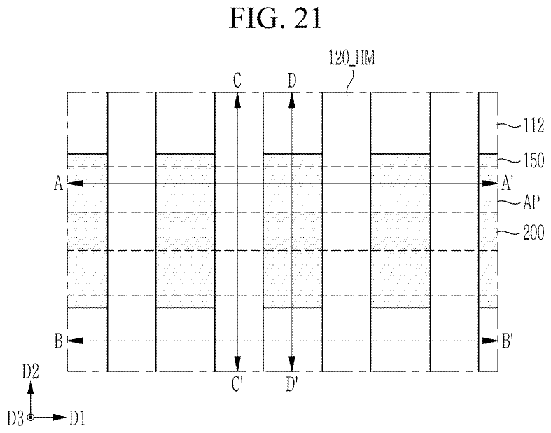

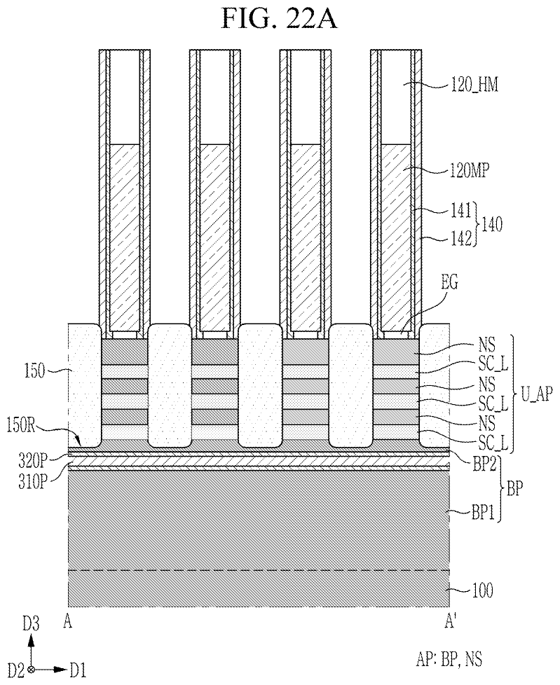

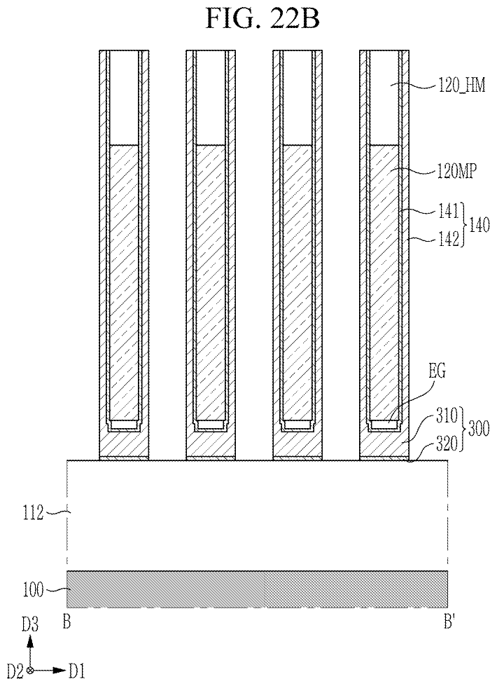

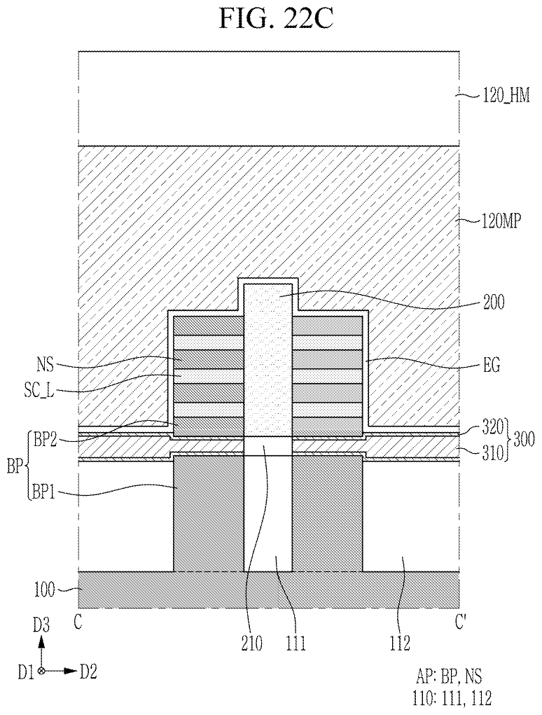

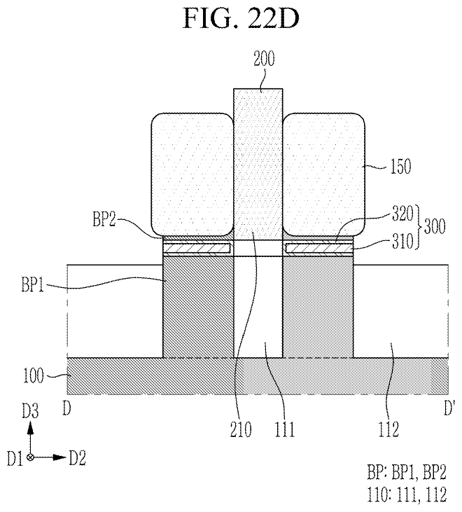

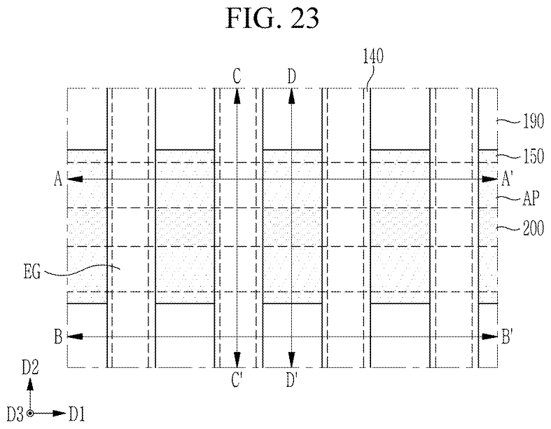

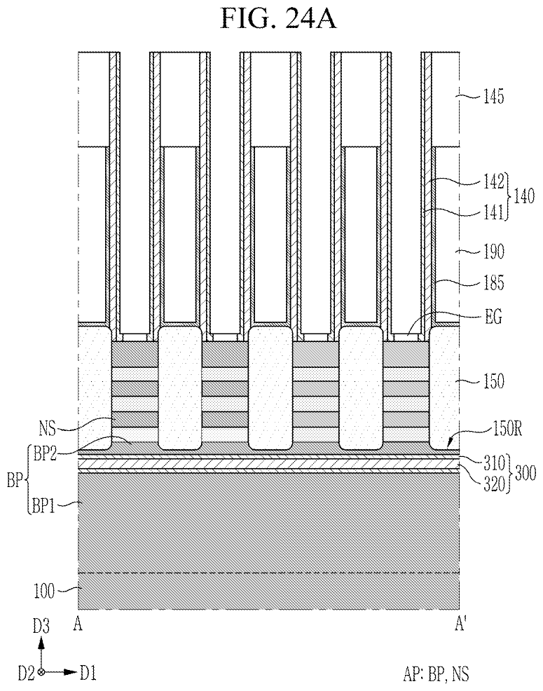

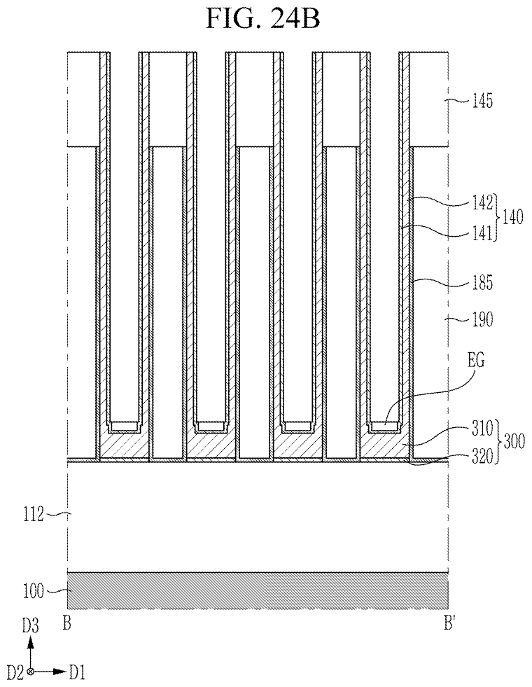

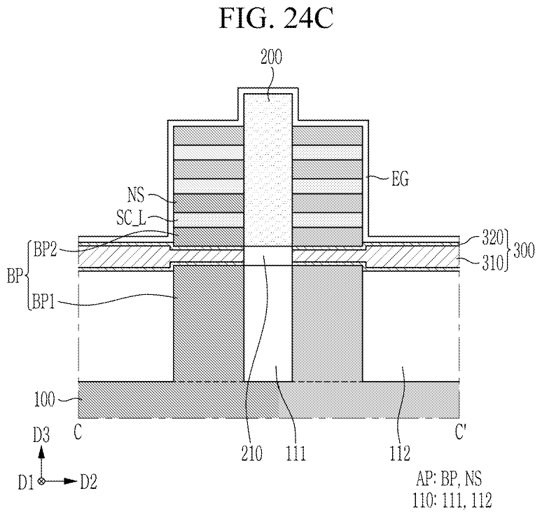

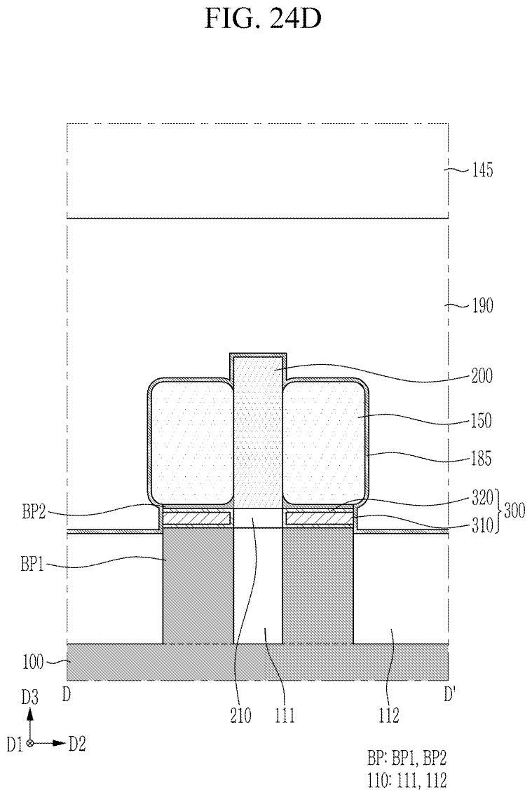

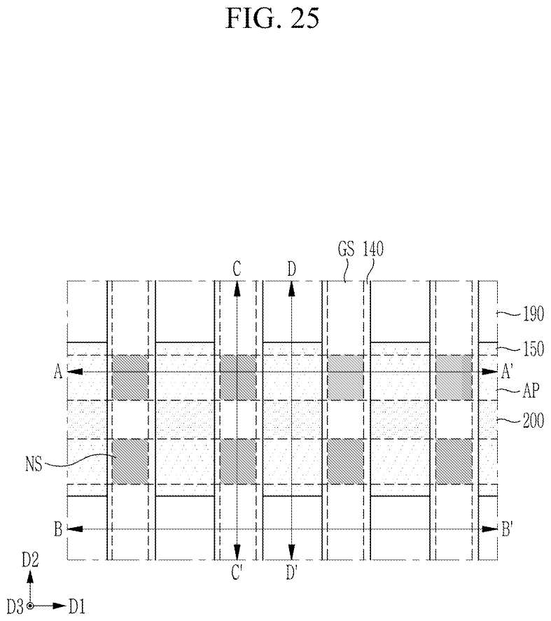

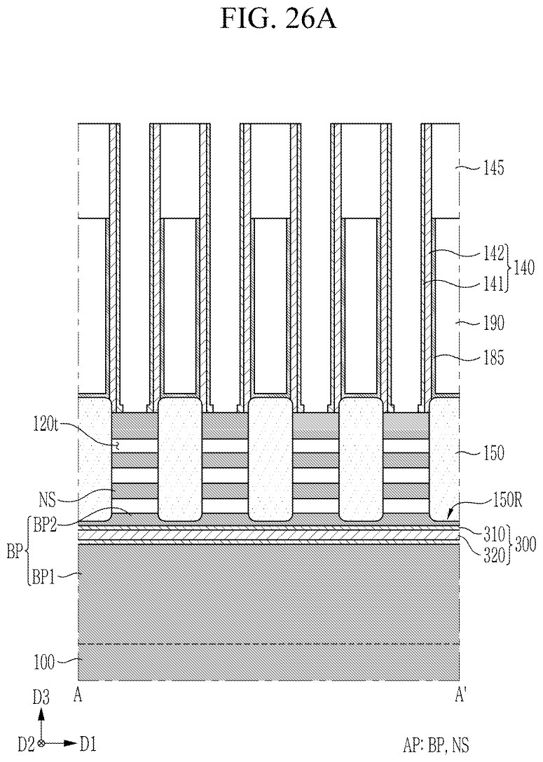

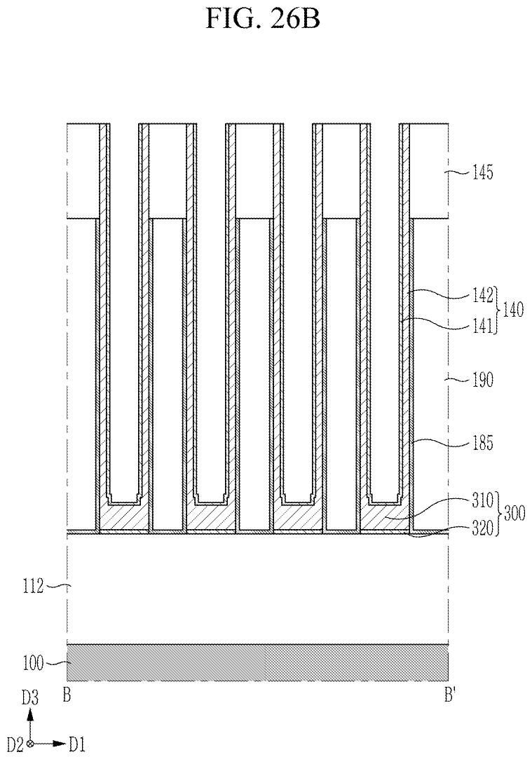

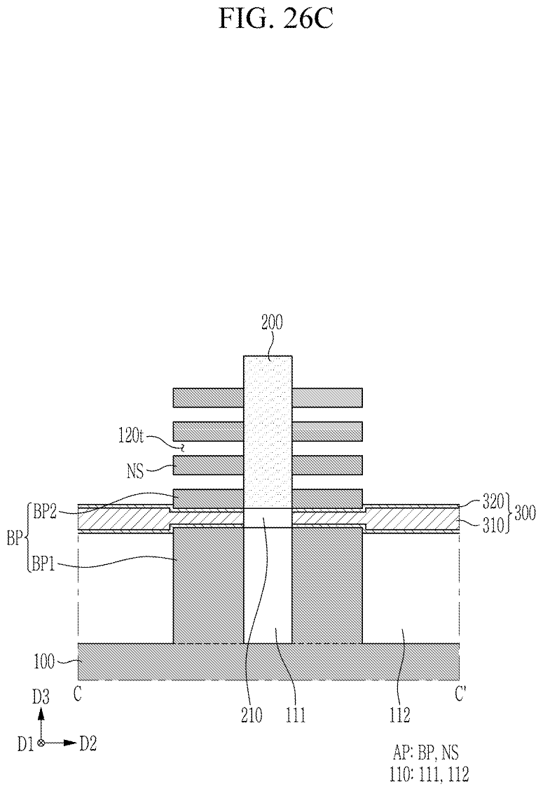

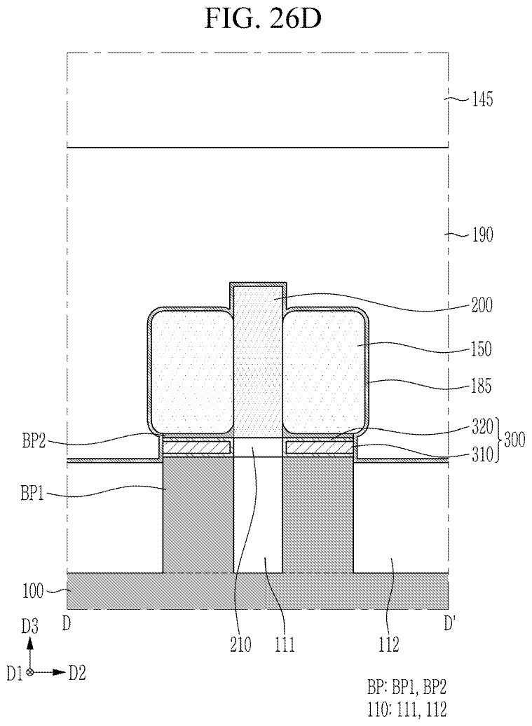

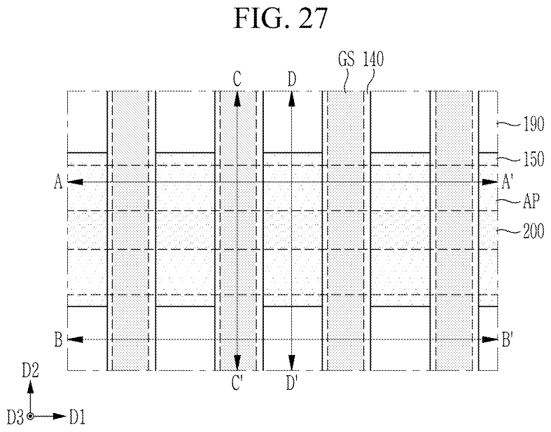

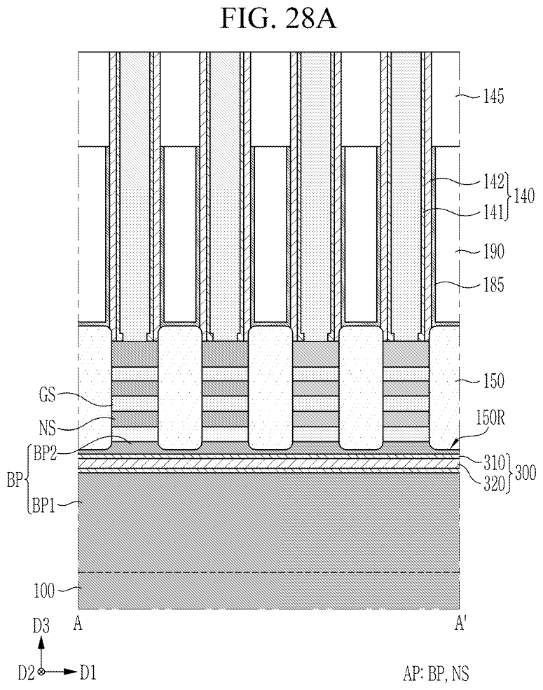

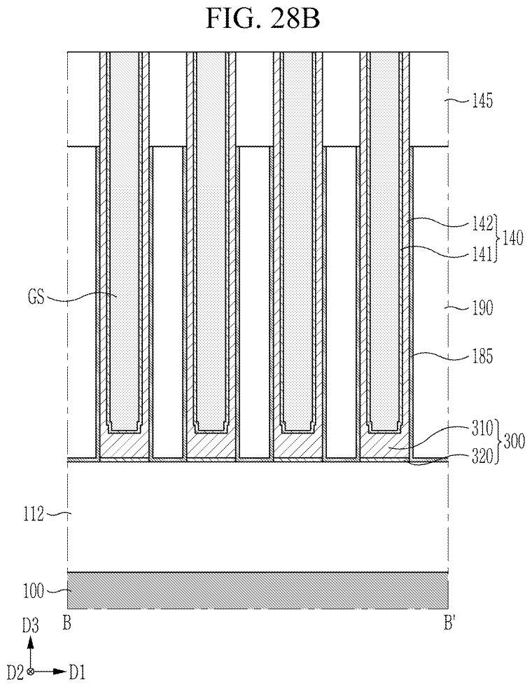

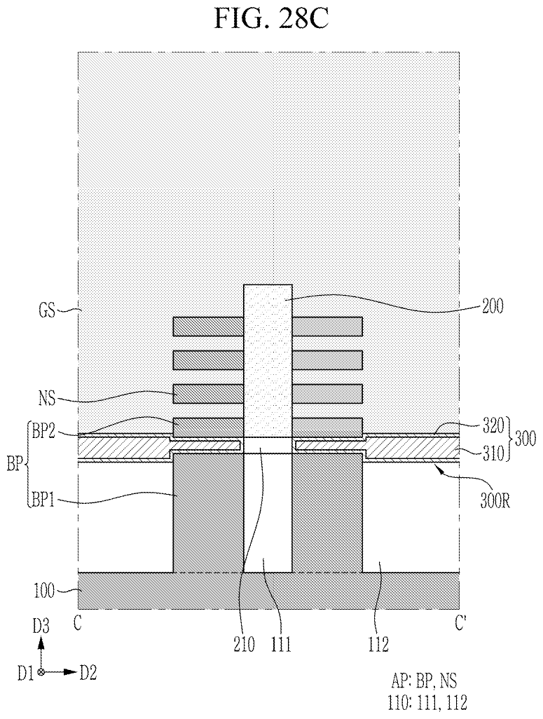

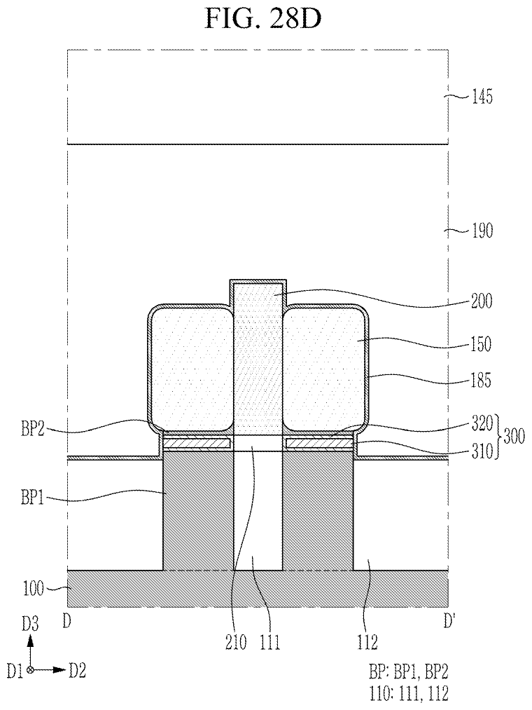

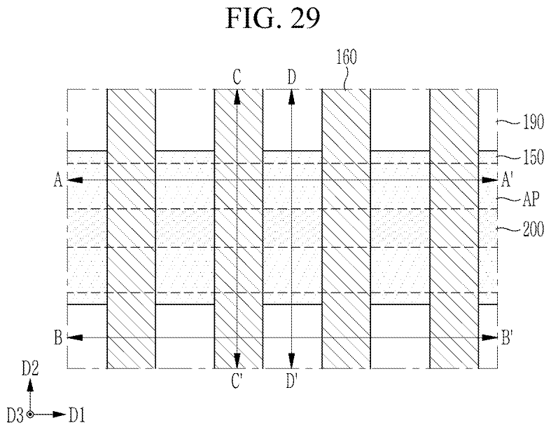

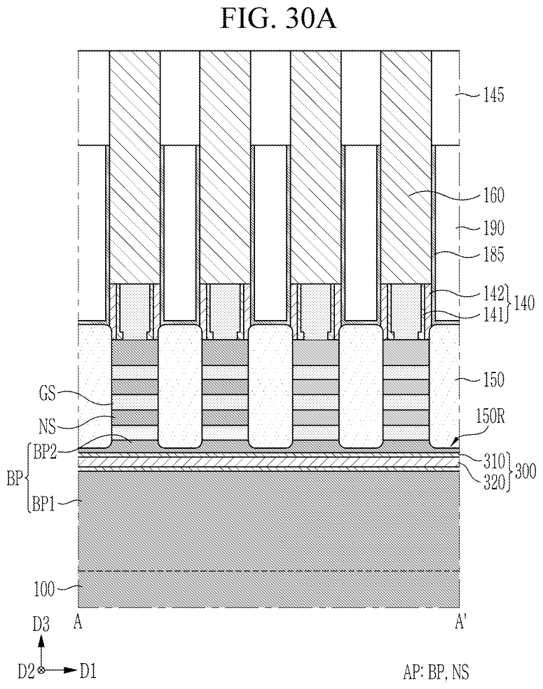

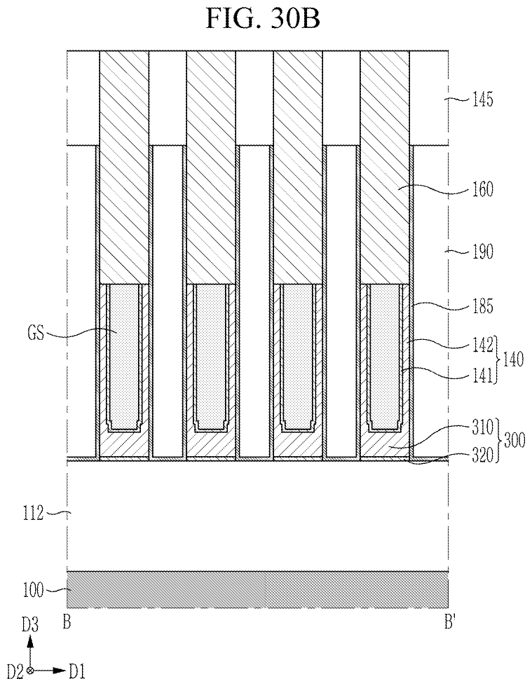

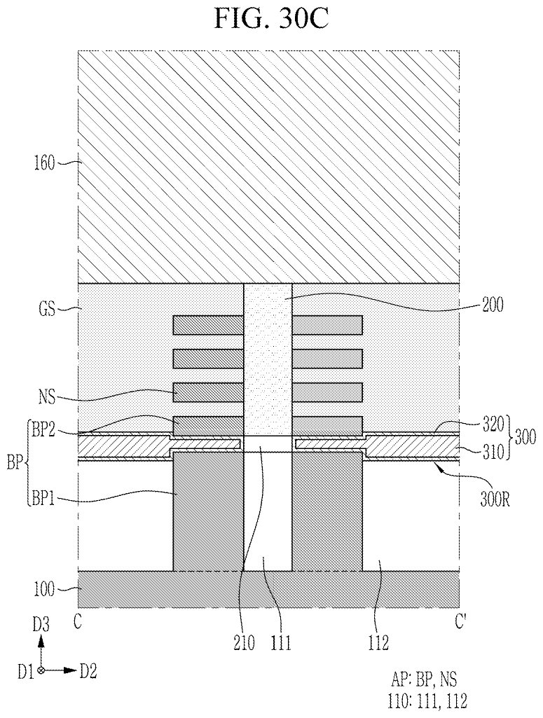

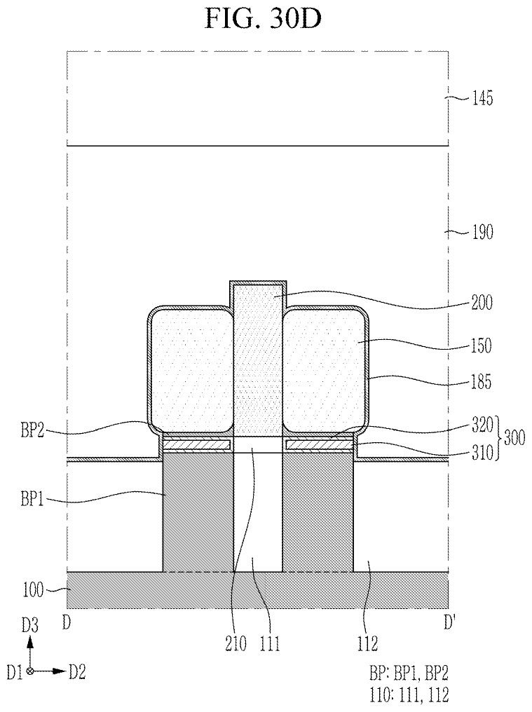

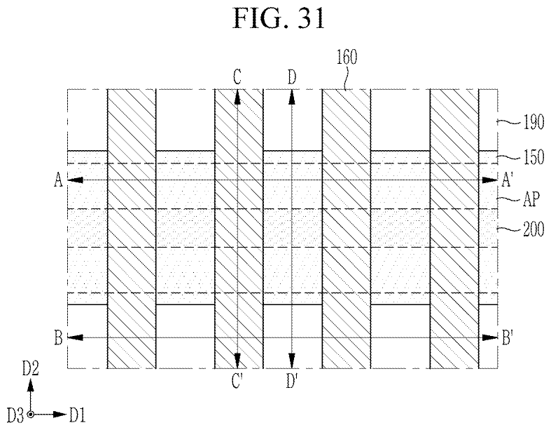

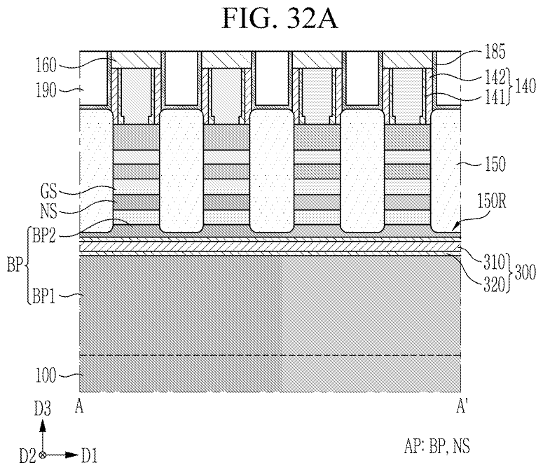

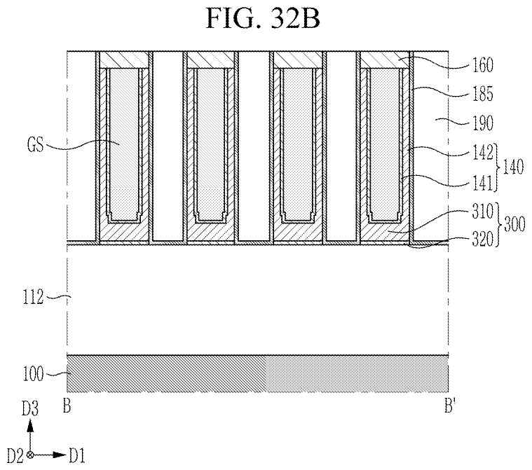

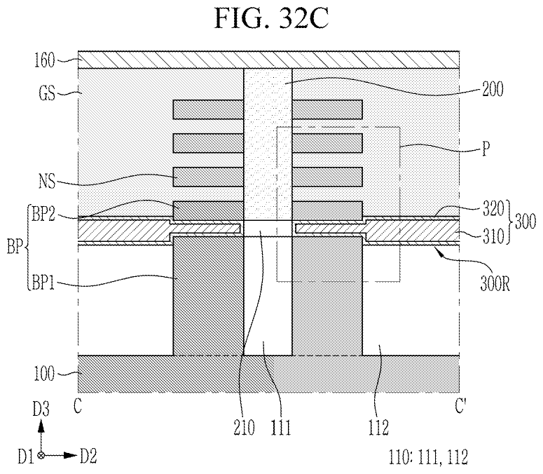

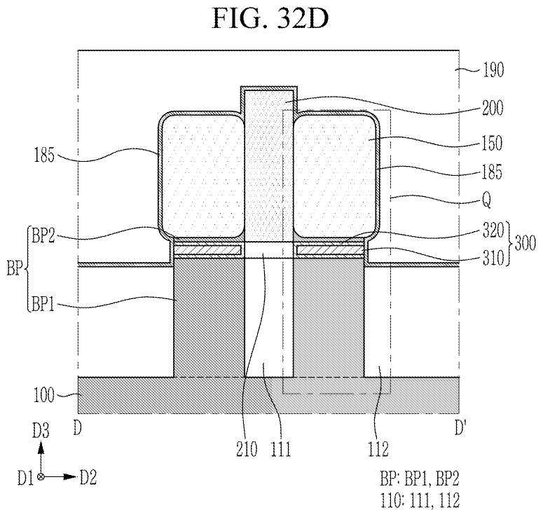

FIG. 14A is a cross-sectional view taken along line A-A′ in FIG. 13. FIG. 14B is a cross-sectional view taken along line B-B′ in FIG. 13. FIG. 14C is a cross-sectional view taken along line C-C′ in FIG. 13. FIG. 14D is a cross-sectional view taken along line D-D′ in FIG. 13. FIG. 16A is a cross-sectional view taken along line A-A′ in FIG. 15. FIG. 16B is a cross-sectional view taken along line B-B′ in FIG. 15. FIG. 16C is a cross-sectional view taken along line C-C′ in FIG. 15. FIG. 16D is a cross-sectional view taken along line D-D′ in FIG. 15. FIG. 18A is a cross-sectional view taken along line A-A′ in FIG. 17. FIG. 18B is a cross-sectional view taken along line B-B′ in FIG. 17. FIG. 18C is a cross-sectional view taken along line C-C′ in FIG. 17. FIG. 18D is a cross-sectional view taken along line D-D′ in FIG. 17. FIG. 20A is a cross-sectional view taken along line A-A′ in FIG. 19. FIG. 20B is a cross-sectional view taken along line B-B′ in FIG. 19. FIG. 20C is a cross-sectional view taken along line C-C′ in FIG. 19. FIG. 20D is a cross-sectional view taken along line D-D′ in FIG. 19. FIG. 22A is a cross-sectional view taken along line A-A′ in FIG. 21. FIG. 22B is a cross-sectional view taken along line B-B′ in FIG. 21. FIG. 22C is a cross-sectional view taken along line C-C′ in FIG. 21. FIG. 22D is a cross-sectional view taken along line D-D′ in FIG. 21. FIG. 24A is a cross-sectional view taken along line A-A′ in FIG. 23. FIG. 24B is a cross-sectional view taken along line B-B′ in FIG. 23. FIG. 24C is a cross-sectional view taken along line C-C′ in FIG. 23. FIG. 24D is a cross-sectional view taken along line D-D′ in FIG. 23. FIG. 26A is a cross-sectional view taken along line A-A′ in FIG. 25. FIG. 26B is a cross-sectional view taken along line B-B′ in FIG. 25. FIG. 26C is a cross-sectional view taken along line C-C′ in FIG. 25. FIG. 26D is a cross-sectional view taken along line D-D′ in FIG. 25. FIG. 28A is a cross-sectional view taken along line A-A′ in FIG. 27. FIG. 28B is a cross-sectional view taken along line B-B′ in FIG. 27. FIG. 28C is a cross-sectional view taken along line C-C′ in FIG. 27. FIG. 28D is a cross-sectional view taken along line D-D′ in FIG. 27. FIG. 30A is a cross-sectional view taken along line A-A′ in FIG. 29. FIG. 30B is a cross-sectional view taken along line B-B′ in FIG. 29. FIG. 30C is a cross-sectional view taken along line C-C′ in FIG. 29. FIG. 30D is a cross-sectional view taken along line D-D′ in FIG. 29. FIG. 32A is a cross-sectional view taken along line A-A′ in FIG. 31. FIG. 32B is a cross-sectional view taken along line B-B′ in FIG. 31. FIG. 32C is a cross-sectional view taken along line C-C′ in FIG. 31. FIG. 32D is a cross-sectional view taken along line D-D′ in FIG. 31.

As shown in FIG. 13, and FIG. 14A to FIG. 14D, on the channel pattern structures U_AP, preliminary gate insulating layers EG, preliminary main gate electrodes 120MP, and preliminary capping layers 120_HM may be formed. As seen in a plan view, the extension directions of the preliminary main gate electrodes 120MP and the preliminary capping layers 120_HM may intersect with the extension direction of the channel pattern structures U_AP. The preliminary main gate electrodes 120MP and the preliminary capping layers 120_HM may extend in the second direction D2 perpendicular to the first direction D1. The preliminary main gate electrodes 120MP may be located at predetermined intervals in the first direction D1.

The preliminary gate insulating layers EG may contain, for example, silicon oxide (SiO₂), but are not limited thereto. The preliminary main gate electrodes 120MP may contain, for example, polysilicon, but are not limited thereto. The preliminary capping layers 120_HM may contain, for example, silicon nitride (SiN), but are not limited thereto.

As shown in FIG. 15, and FIG. 16A to FIG. 16D, the sacrificial insulating patterns 220 may be removed by performing an etching process. The etching process may be performed in a wet etching manner, but is not limited thereto. As described above, the sacrificial insulating patterns 220 may contain a material having etch selectivity to the second field insulating layer 112. Therefore, although the second field insulating layer 112 are exposed as the sacrificial insulating patterns 220 are etched, the upper surface of the second field insulating layer 112 may not be removed.

As the sacrificial insulating patterns 220 are removed, first openings OP1 may be formed. By the first openings OP1, portions of the preliminary gate insulating layers EG, the second field insulating layer 112, and the sacrificial insulating layers SP may be exposed.

As shown in FIG. 17, and FIG. 18A to FIG. 18D, the sacrificial insulating layers SP may be removed by performing an etching process. The etching process may be performed in a wet etching manner, but is not limited thereto. As described above, the sacrificial insulating layers SP may contain a material having etch selectivity to the lower patterns BP. Therefore, although the first lower patterns BP1 and the second lower patterns BP2 are exposed as the sacrificial insulating layers SP are etched, the upper surface of the first lower patterns BP1 and the lower surface of the second lower patterns BP2 may not be removed.

As the sacrificial insulating layers SP are removed, the recesses 300R may be formed. By the recesses 300R, portions of the first lower patterns BP1, the second lower patterns BP2, and the insulating patterns 210 may be exposed. Specifically, by the recesses 300R, the upper surface of the first lower patterns BP1, the lower surface of the second lower patterns BP2, and the side surfaces (e.g., the opposite side surfaces) of the insulating patterns 210 may be exposed. In this case, as described above, the thickness of the sacrificial insulating patterns 220 in the third direction D3 may be larger than the thickness of the sacrificial insulating layers SP in the third direction D3. Therefore, the distance in the third direction D3 between the first lower patterns BP1 and the second lower patterns BP2 in the recesses 300R may be smaller than the distance in the third direction D3 between the preliminary gate insulating layers EG and the second field insulating layer 112 in the recesses 300R.

As shown in FIG. 19, and FIG. 20A to FIG. 20D, in the recesses 300R, a preliminary protective liner 320P and a preliminary protective insulating layer 310P may be sequentially formed.

First, the preliminary protective liner 320P may be formed in the recesses 300R. Specifically, the preliminary protective liner 320P may be formed on the upper surface of the second field insulating layer 112, the upper surface of the first lower patterns BP1, the side surfaces of the insulating patterns 210, the lower surface of the second lower patterns BP2, and the lower surface of the preliminary gate insulating layers EG exposed by the recesses 30CR so as to conform to them. Therefore, the preliminary protective liner 320P may be formed along the profiles of the recesses 300R. In this case, as shown in FIG. 20D, the preliminary protective liner 320P may be formed on the side surfaces of the channel pattern structures U_AP, at least some portions of the upper surface of the channel pattern structures U_AP, and at least some portions of the buried insulating structure 200. The preliminary protective liner 320P may be formed using an atomic layer deposition (ALD) process, a chemical vapor deposition (CVD) process, etc.

Also, while the preliminary protective liner 320P are formed, first preliminary gate spacers 141P may be formed on both side surfaces (e.g., the opposite side surfaces) of each of the preliminary main gate electrode 120MP, both side surfaces (e.g., the opposite side surfaces) of each of the preliminary capping layer 120_HM, and the upper surface of the preliminary capping layers 120_HM. Each first preliminary gate spacer 141P may be formed so as to conform to the profile of both side surfaces (e.g., the opposite side surfaces) of a preliminary main gate electrode 120MP, both side surfaces (e.g., the opposite side surfaces) of a preliminary capping layer 120_HM, and the upper surface of the preliminary capping layer 120_HM. Each first preliminary gate spacer 141P may be formed integrally with the preliminary protective liner 320P. The first preliminary gate spacers 141P may contain the same material as that in the preliminary protective liner 320P.

Subsequently, on the preliminary protective liner 320P, the preliminary protective insulating layer 310P may be formed. The preliminary protective insulating layer 310P may, at least partially, fill the recesses 300R. The preliminary protective insulating layer 310P may be located between the preliminary gate insulating layers EG and the second field insulating layer 112, and between the second lower patterns BP2 and the first lower patterns BP1. In other words, as shown in FIG. 20D, the preliminary protective insulating layer 310P may be formed even on the preliminary protective liner 320P formed on the side surfaces of the channel pattern structures U_AP, at least some portions of the upper surface of the channel pattern structures U_AP, and at least some portions of the buried insulating structure 200. The preliminary protective insulating layer 310P may be formed using an atomic layer deposition (ALD) process, a chemical vapor deposition (CVD) process, etc.

Further, on the first preliminary gate spacers 141P, second preliminary gate spacers 142P may be formed. The second preliminary gate spacers 142P may contain the same material as that in the preliminary protective insulating layer 310P.

As shown in FIG. 21, and FIG. 22A to FIG. 22D, the source/drain patterns 150 may be formed on the second lower patterns BP2.

First, at least some portions of the exposed preliminary protective insulating layer 310P and the exposed preliminary protective liner 320P may be sequentially etched by performing an etching process. The etching process may be performed in a dry etching process manner, but is not limited thereto. As the etching process proceeds, portions of the preliminary protective insulating layer 310P located between adjacent preliminary main gate electrodes 120MP may be removed. Also, as the etching process proceeds, portions of the preliminary protective liner 320P located between adjacent preliminary main gate electrodes 120MP may be removed.

Accordingly, as shown in FIG. 22A and FIG. 22B, at least some portions of the preliminary protective liner 320P and at least some portions of the preliminary protective insulating layer 310P which do not overlap the preliminary main gate electrode 120MP in the third direction D3 may be removed. In this case, portions of the preliminary protective liner 320P and portions of the preliminary protective insulating layer 310P overlapping the preliminary main gate electrode 120MP in the third direction D3 may not be etched. In some embodiments, some portions of the upper surface of the channel pattern structures U_AP may be exposed. Some portions of the upper surface of the second field insulating layer 112 may be exposed.

At this time, the preliminary protective insulating layer 310P and the preliminary protective liner 320P located on the side surfaces of the channel pattern structures U_AP, at least some portions of the upper surface of the channel pattern structures U_AP, and at least some portions of the buried insulating structure 200 may be removed together.

Subsequently, at least some portions of the channel pattern structures U_AP are etched using the preliminary main gate electrode 120MP and the preliminary gate spacers 140P as a mask, such that the source/drain recesses 150R may be formed.

As the source/drain recesses 150R are formed, active patterns ACT_L are separated, whereby the channel patterns NS may be formed. On both sides of each source/drain recess 150R, the channel patterns NS may be located. Structures in which the channel patterns NS and sacrificial patterns SC_L are alternately stacked may be provided.

Subsequently, in the source/drain recesses 150R, the source/drain patterns 150 may be formed. The source/drain patterns 150 may be formed on the second lower patterns BP2 of the substrate 100. The source/drain patterns 150 may be formed using an epitaxial growth method.

As shown in FIG. 23, and FIG. 24A to FIG. 24D, the etch stop films 185, the interlayer insulating layers 190, and capping layers 145 may be sequentially formed on the source/drain patterns 150. Subsequently, some portions of the capping layers 145 and the preliminary capping layers 120_HM may be removed such that the upper surface of the preliminary main gate electrode 120MP are exposed. At this time, some portions of the preliminary gate spacers 140P may be removed together, whereby the gate spacers 140 may be formed.

Subsequently, the preliminary main gate electrode 120MP may be removed, whereby the preliminary gate insulating layers EG may be exposed.

As shown in FIG. 25, and FIG. 26A to FIG. 26D, the preliminary gate insulating layers EG may be removed, whereby the channel pattern structures U_AP between the gate spacers 140 may be exposed. Subsequently, the plurality of gate sacrifice patterns SC_L located between the channel patterns NS may be removed, whereby gate trenches 120t are formed between the channel patterns NS.

As shown in FIG. 27, and FIG. 28A to FIG. 28D, the gate structures GS may be formed in the gate trenches 120t. The gate structures GS may be formed by filling the gate trenches 120t with a conductive material and performing a planarizing process.

Subsequently, as shown in FIG. 29, and FIG. 30A to FIG. 30D, at least some portions of the gate structures GS may be removed using the capping layers 145 as a mask, whereby the gate capping layers 160 may be formed. The gate capping layers 160 may contain, for example, silicon nitride (SiN), silicon oxynitride (SiON), silicon (Si), silicon carbonitride (SiCN), silicon oxycarbonitride (SiOCN), and/or combinations thereof.

Finally, as shown in FIG. 31, and FIG. 32A to FIG. 32D, the interlayer insulating layers 190, the etch stop films 185, and the gate capping layers 160 may be etched such that their thicknesses decrease. Thereafter, the upper insulating layer 195 may be formed on the interlayer insulating layers 190, the etch stop films 185, and the gate capping layers 160, whereby the semiconductor device according to FIG. 1 and FIG. 2A to FIG. 2D may be formed.

The gate structures GS may be formed using an atomic layer deposition (ALD) process, a chemical vapor deposition (CVD) process, etc. The gate structures GS may contain doped polysilicon, a metal, a conductive metal nitride, a conductive metal carbide, and/or a combination thereof. However, this is merely an example, and the material of the gate structures GS is not limited thereto.

When the semiconductor device according to some embodiments is manufactured, in the process of forming the lower patterns BP, the sacrificial insulating layers SP may be formed, and in the process of forming the field insulating layers 110, the sacrificial insulating patterns 220 may be formed. Thereafter, the sacrificial insulating layers SP and the sacrificial insulating patterns 220 may be removed, whereby the protective liner 320 and the protective insulating layer 310 may be individually formed. Therefore, it is possible to prevent the level of the second field insulating layer 112 from lowering in the subsequent processes.

Since the second field insulating layer 112 may be protected by the protective liner 320 and the protective insulating layer 310, when the gate structures GS are formed, it is possible to reduce leakage current occurring between the gate structures GS and the first lower patterns BP1 and between the gate structures GS and the source/drain patterns 150 adjacent thereto. Therefore, it is possible to improve the reliability of the semiconductor device.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor device comprising:
a substrate;
a first lower pattern on the substrate;
a second lower pattern on the first lower pattern;
channel patterns on the second lower pattern;
a first field insulating layer on a first side surface of the first lower pattern;
a second field insulating layer on a second side surface of the first lower pattern;
a buried insulating structure on the first field insulating layer and on side surfaces of the channel patterns;
a protective layer on the second field insulating layer;
source/drain patterns on opposite sides of each of the channel patterns; and
a gate electrode extending around at least some portions of the channel patterns and the buried insulating structure,
wherein the protective layer comprises:
a protective insulating layer between the first lower pattern and the second lower pattern, and between the gate electrode and the second field insulating layer; and
a protective liner extending around the protective insulating layer.

2. The semiconductor device of claim 1, wherein
the protective insulating layer comprises:
a first part between the first lower pattern and the second lower pattern; and
a second part between the second field insulating layer and the gate electrode, and
a first thickness of the first part of the protective insulating layer is smaller than or equal to a second thickness of the second part of the protective insulating layer.

3. The semiconductor device of claim 2, wherein
an upper surface of the first part of the protective insulating layer is closer to an upper surface of the substrate than an upper surface of the second part of the protective insulating layer, or the upper surface of the first part of the protective insulating layer is at a same distance from the upper surface of the substrate as the upper surface of the second part of the protective insulating layer.

4. The semiconductor device of claim 3, wherein
a lower surface of the first part of the protective insulating layer is farther from the upper surface of the substrate than a lower surface of the second part of the protective insulating layer, or the lower surface of the first part of the protective insulating layer is at a same distance from the upper surface of the substrate as the lower surface of the second part of the protective insulating layer.

5. The semiconductor device of claim 1, wherein
the protective liner further comprises:
a first horizontal part between the protective insulating layer and the second lower pattern; and
a second horizontal part between the protective insulating layer and the gate electrode,
wherein an upper surface of the first horizontal part is closer to an upper surface of the substrate than an upper surface of the second horizontal part.

6. The semiconductor device of claim 5, wherein
the upper surface of the first horizontal part is closer to the upper surface of the substrate than a lower surface of the gate electrode.

7. The semiconductor device of claim 5, wherein
the first horizontal part overlaps the source/drain patterns in a direction perpendicular to the upper surface of the substrate.

8. The semiconductor device of claim 5, wherein
the protective liner comprises:
a third horizontal part between the protective insulating layer and the first lower pattern; and
a fourth horizontal part between the protective insulating layer and the second field insulating layer,
wherein a lower surface of the third horizontal part is farther from the upper surface of the substrate than a lower surface of the fourth horizontal part.

9. The semiconductor device of claim 8, wherein
the lower surface of the third horizontal part is farther from the upper surface of the substrate than an upper surface of the second field insulating layer.

10. A semiconductor device comprising:
a substrate;
a first lower pattern extending in a first direction on the substrate;
a second lower pattern on the first lower pattern;
channel patterns on the second lower pattern;
a first field insulating layer on a first side surface of the first lower pattern;
a second field insulating layer on a second side surface of the first lower pattern;
a buried insulating structure extending in the first direction on the first field insulating layer and on side surfaces of the channel patterns;
source/drain patterns on opposite sides of each of the channel patterns;
a gate electrode extending in a second direction intersecting with the first direction and extending around at least some portions of the channel patterns and the buried insulating structure; and
a protective layer between the first lower pattern and the second lower pattern, and between the second field insulating layer and the gate electrode, wherein
a first thickness of the protective layer between the first lower pattern and the second lower pattern is smaller than or equal to a second thickness of the protective layer between the second field insulating layer and the gate electrode.

11. The semiconductor device of claim 10, wherein
an upper surface of the protective layer between the second field insulating layer and the gate electrode is farther from an upper surface of the substrate than a lower surface of the second lower pattern.

12. The semiconductor device of claim 11, wherein
a lower surface of the gate electrode is farther from the upper surface of the substrate than an upper surface of the first lower pattern.

13. The semiconductor device of claim 11, further comprising:
gate spacers on opposite sides of the gate electrode, wherein
the gate spacers and the protective layer include a same material.

14. The semiconductor device of claim 10, wherein
the protective layer includes a protective insulating layer in a recess between the first lower pattern and the second lower pattern and between the gate electrode and the second field insulating layer, and
the protective insulating layer comprises:
a first part of the protective insulating layer between the second lower pattern and the first lower pattern; and
a second part of the protective insulating layer extending in the second direction from the first part of the protective insulating layer between the gate electrode and the second field insulating layer,
wherein a second thickness of the second part of the protective insulating layer is larger than or equal to a first thickness of the first part of the protective insulating layer.

15. The semiconductor device of claim 14, wherein
the protective layer further includes a protective liner on a lower surface, side surfaces, and an upper surface of the protective insulating layer, and
the protective liner includes silicon nitride, and the protective insulating layer includes silicon oxycarbonitride.

16. A semiconductor device comprising:
a substrate;
a first lower pattern on the substrate;
a second lower pattern on the first lower pattern;
channel patterns on the second lower pattern;
a first field insulating layer on a first side surface of the first lower pattern;
a second field insulating layer on a second side surface of the first lower pattern;
a buried insulating structure on the first field insulating layer and on side surfaces of the channel patterns;
a protective layer on the second field insulating layer;
source/drain patterns on opposite sides of each of the channel patterns; and
a gate electrode extending around at least some portions of the channel patterns and the buried insulating structure, wherein
the protective layer comprises:
a protective insulating layer between the first lower pattern and the second lower pattern, and between the gate electrode and the second field insulating layer; and
a protective liner extending around the protective insulating layer, and
wherein a first distance between the second lower pattern and the first lower pattern is smaller than or equal to a second distance between the gate electrode and the second field insulating layer.

17. The semiconductor device of claim 16, wherein
the protective insulating layer comprises:
a first part between the first lower pattern and the second lower pattern; and
a second part between the second field insulating layer and the gate electrode,
wherein a first thickness of the first part of the protective insulating layer is smaller than or equal to a second thickness of the second part of the protective insulating layer.

18. The semiconductor device of claim 17, wherein
a lower surface of the first part of the protective insulating layer is farther from an upper surface of the substrate than a lower surface of the second part of the protective insulating layer, or the lower surface of the first part of the protective insulating layer is at a same distance from the upper surface of the substrate as the lower surface of the second part of the protective insulating layer.

19. The semiconductor device of claim 16, further comprising:
an insulating pattern between the buried insulating structure and the first field insulating layer,
wherein the insulating pattern is on a side surface of the protective layer.

20. The semiconductor device of claim 19, wherein
the buried insulating structure is on a side surface of the second lower pattern.
